(19) United States
(12) Patent Application Publication
(10) Pub. No.: US 2026/0114303 A1
(43) Pub. Date: Apr. 23, 2026

(54) MINIATURE DUMMY METAL STRUCTURES FOR STRESS REDUCTION IN SEMICONDUCTOR DIES AND METHODS FOR FORMING THE SAME

(71) Applicant: Taiwan Semiconductor Manufacturing Company Limited, Hsinchu (TW)

(72) Inventors: Yi-Chen LI, Taichung City (TW); Jen-Yuan CHANG, Hsinchu City (TW)

(21) Appl. No.: 18/921,234

(22) Filed: Oct. 21, 2024

(51) Int. Cl. H01L 23/498; H01L 21/768; H01L 23/00; H01L 23/31; H01L 25/065

(52) U.S. Cl. CPC H10W 70/65; H10W 20/043; H10W 20/054; H10W 90/701; H10W 70/635; H10W 72/952; H10W 74/141; H10W 90/00; H10W 90/722; H10W 90/792; H10W 90/794

(57) ABSTRACT

A device structure may be manufactured by forming metal interconnect structures embedded in dielectric material layers over a substrate; forming active metal connection structures, primary dummy metal structures, and miniature dummy metal structures over a topmost dielectric material layer selected from the dielectric material layers, wherein the miniature dummy metal structures have a lesser height than the active metal connection structures and the primary dummy metal structures; and forming bonding pads over the active metal connection structures, the primary dummy metal structures, and the miniature dummy metal structures, wherein the active metal connection structures and the primary dummy metal structures are contacted by the bonding pads, and the miniature dummy metal structures are not contacted by any of the bonding pads.

### BACKGROUND

In semiconductor manufacturing, integrating advanced interconnect structures poses substantial challenges, particularly in managing stress and preventing defects during the fabrication process. Copper structures may generate internal stress during thermal processes, which often leads to cracking of dielectric materials and peeling of thin films. Issues related to stress are further complicated by variations in the physical characteristics of the copper structures, resulting in non-uniform surfaces. Non-uniform surfaces may create difficulties during subsequent processing steps, leading to over-etching and/or exposure of the copper to plasma, which causes arcing defects. Problems associated with stress and non-uniformity undermine the reliability and yield of semiconductor devices, highlighting the need for more effective approaches to manage stress during semiconductor manufacturing processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for the clarity of discussion.

FIG. 1 is a vertical cross-sectional view of an exemplary structure after formation of semiconductor devices and metal interconnect structures formed within dielectric material layers according to an embodiment of the present disclosure.

FIG. 2A-2G are sequential vertical cross-sectional views of a region of the exemplary structure during formation of active metal connection structures, primary dummy metal structures, and miniature dummy metal structures according to a first embodiment of the present disclosure.

FIG. 2H is a top-down view of a region of the exemplary structure after formation of the active metal connection structures, the primary dummy metal structures, and the miniature dummy metal structures according to an embodiment of the present disclosure.

FIG. 3A-3G are sequential vertical cross-sectional views of a region of the exemplary structure during formation of active metal connection structures, primary dummy metal structures, and miniature dummy metal structures according to a second embodiment of the present disclosure.

FIG. 4A-4F are sequential vertical cross-sectional views of a region of the exemplary structure during planarization of the active metal connection structures, the primary dummy metal structures, and the miniature dummy metal structures and formation of bonding pads according to an embodiment of the present disclosure.

FIG. 5 is a vertical cross-sectional view of the exemplary structure after formation of the bonding pads.

FIG. 6A is a vertical cross-sectional view of a region of a reconstituted wafer around a first semiconductor die according to an embodiment of the present disclosure.

FIG. 6B is a top-down view of the in-process reconstituted wafer.

FIG. 7 is a vertical cross-sectional view of a region of the reconstituted wafer after formation of a first molding compound matrix according to an embodiment of the present disclosure.

FIG. 8 is a vertical cross-sectional view of a region of the reconstituted wafer after formation of a first bonding-level dielectric layer and first active bonding pads according to an embodiment of the present disclosure.

FIG. 9 is a vertical cross-sectional view of a region of the reconstituted wafer after attaching a second semiconductor die to each first semiconductor die according to an embodiment of the present disclosure.

FIG. 10A is a vertical cross-sectional view of a region of the reconstituted wafer after formation of a second molding compound matrix according to an embodiment of the present disclosure.

FIG. 10B is a top-down view of the region of the reconstituted wafer of FIG. 10A.

FIG. 11 is a first flowchart illustrating steps for forming a device structure according to an embodiment of the present disclosure.

FIG. 12 is a second flowchart illustrating steps for forming a device structure according to an embodiment of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

According to an aspect of the present disclosure, a device structure may be manufactured in a manner that addresses the challenges of stress management and defect prevention during the fabrication of copper-containing structures. The process begins with forming metal interconnect structures within dielectric material layers over a substrate. Subsequently, active metal connection structures, primary dummy metal structures, and miniature dummy metal structures may be formed over the topmost dielectric material layer. The miniature dummy metal structures, designed with a lesser height than both the active metal connection structures and the primary dummy metal structures, may be specifically formed in narrow areas that are too small to accommodate primary dummy metal structures. The various embodiment designs promote the distribution of the copper more uniformly across the semiconductor surface. As a result, internal stresses generated during thermal processes may be reduced and issues such as cracking and peeling in the dielectric materials may be mitigated against.

The metal structures may be formed by depositing a continuous metallic seed layer over the dielectric material layers, followed by applying a patterned electroplating mask layer. Metallic material may be electroplated onto the physically exposed surfaces of the continuous metallic seed layer. After removing the patterned electroplating mask layer and unmasked portions of the continuous metallic seed layer, the remaining portions of the seed layer and the electroplated material constitute the active metal connection structures, the primary dummy metal structures, and the miniature dummy metal structures. The miniature dummy metal structures may be electrically isolated from the metal interconnect structures, bonding pads, active metal connection structures, and primary dummy metal structures, thereby aiding stress management and reliability of the semiconductor device.

According to an aspect of the present disclosure, a device structure with reduced stress level is provided, which includes metal interconnect structures formed within dielectric material layers. Active metal connection structures, primary dummy metal structures, and miniature dummy metal structures may be provided over the dielectric material layers. The miniature dummy metal structures, formed in areas too narrow for primary dummy metal structures, assist in the uniform distribution of copper, helping to reduce stress. Bonding pads may be positioned over the active metal connection structures and primary dummy metal structures, making contact with these components, while the miniature dummy metal structures remain uncontacted by the bonding pads, ensuring their isolation and supporting the device's reliability.

According to another aspect of the present disclosure, bonding pads may be formed over the metal structures. The bonding pads may be configured to contact the active metal connection structures and the primary dummy metal structures but do not contact the miniature dummy metal structures. Such selective contact maintains the structural integrity and reliability of the semiconductor device. Additionally, the method outlines the formation of connection-level dielectric layers and bonding-level dielectric layers over the metal structures. The connection-level dielectric layer may be planarized to ensure uniformity, and pad cavities may be formed through the bonding-level dielectric layer to expose the top surfaces of the active metal connection structures and primary dummy metal structures, enabling the formation of bonding pads.

Embodiments of the present disclosure provide a device structure that manages internal stress and mitigates against defects such as cracking, peeling, and arcing. The inclusion of miniature dummy metal structures in narrow areas, where primary dummy metal structures may not be formed, is part of this approach. By enhancing the uniformity of copper distribution, these miniature dummy metal structures reduce stress, which in turn improves the yield and reliability of semiconductor devices, particularly in applications requiring high-density interconnects and precise stress management in semiconductor manufacturing processes. The various aspects of the present disclosure are now described with reference to accompanying drawings.

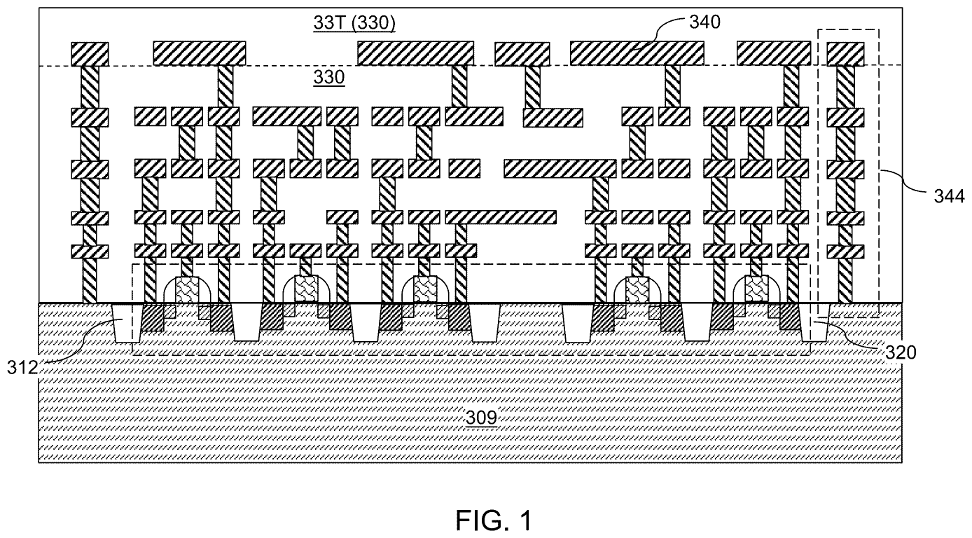

Referring to FIG. 1, an exemplary structure is illustrated, which includes semiconductor devices 320 formed on a semiconductor substrate 309, and metal interconnect structures 340 may be formed within dielectric material layers 330 and overlying the semiconductor devices 320. The semiconductor devices 320 may comprise field effect transistors, junction transistors, resistors, capacitors, inductors, diodes, and/or other semiconductor devices known in the art. In one embodiment, the semiconductor devices 320 may comprise complementary metal oxide semiconductor (CMOS) devices known in the art. The various semiconductor devices 320 may be electrically isolated from one another by shallow trench isolation structures 312.

The dielectric material layers 330 may comprise, and/or may consist of, inorganic dielectric materials such as silicate glass materials, silicon nitride, silicon carbide nitride, silicon oxynitride, and/or dielectric metal oxide materials. The metal interconnect structures 340 may comprise metal line structures, metal via structures, and/or metal pads. A subset of the metal interconnect structures 340 may laterally surround the semiconductor devices 320 and the rest of the metal interconnect structures 340 as a continuous wall structure, and may constitute an edge seal ring structure 344. In one embodiment, via-level metal interconnect structures and line-level metal interconnect structures may vertically alternate along the vertical direction. The total number of metal line levels within the metal interconnect structures 340 may be in a range from 1 to 20, such as from 2 to 10. In one embodiment, a topmost dielectric material layer 33T selected from the dielectric material layers 330 may comprise a via-level dielectric material layer.

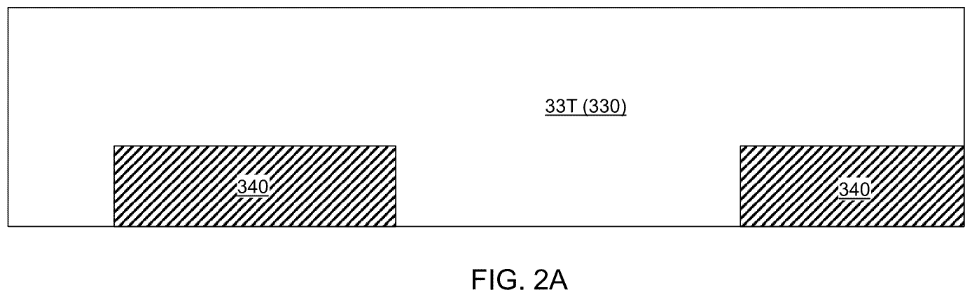

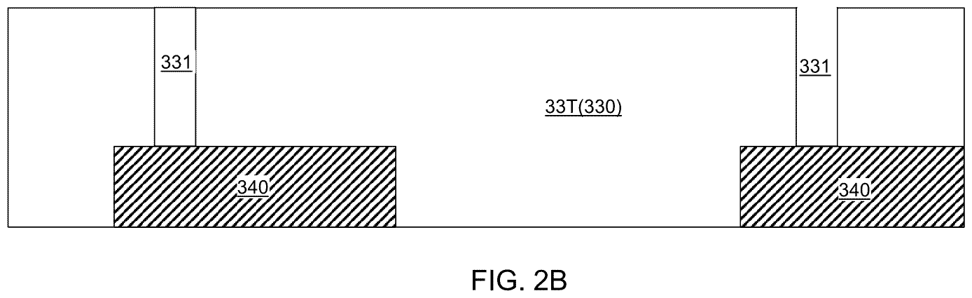

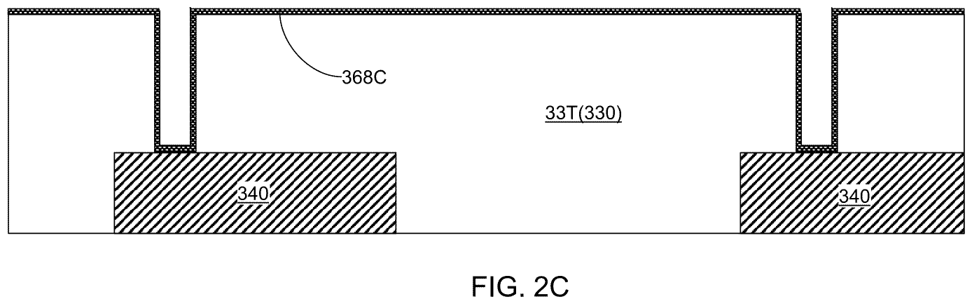

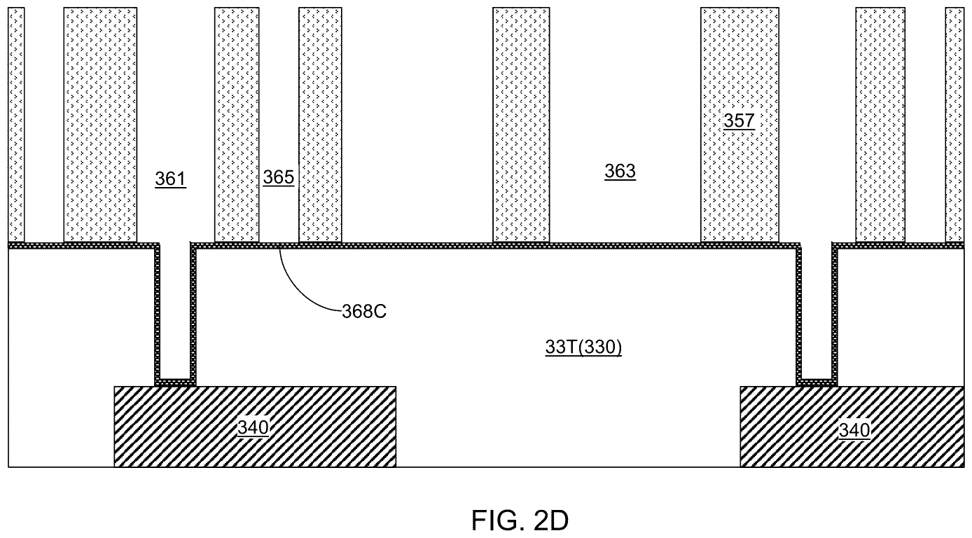

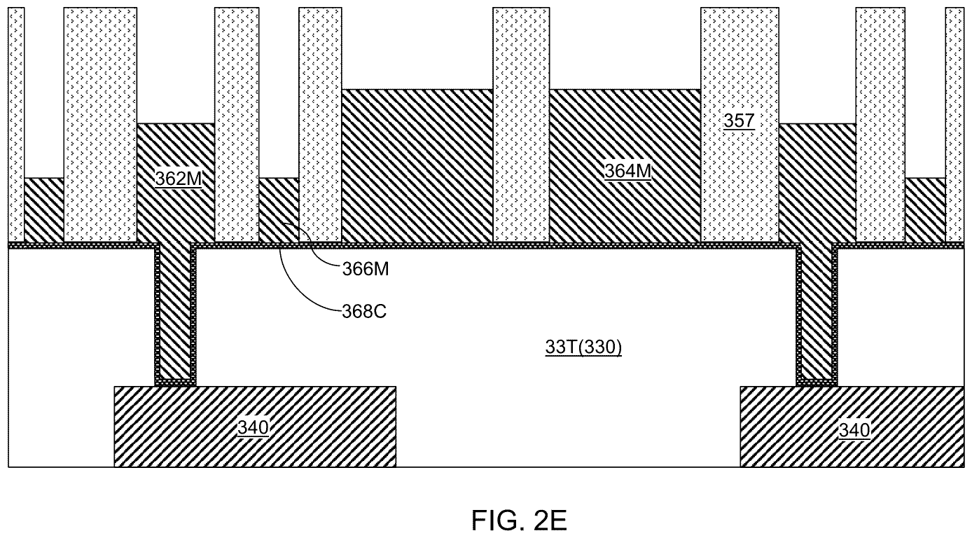

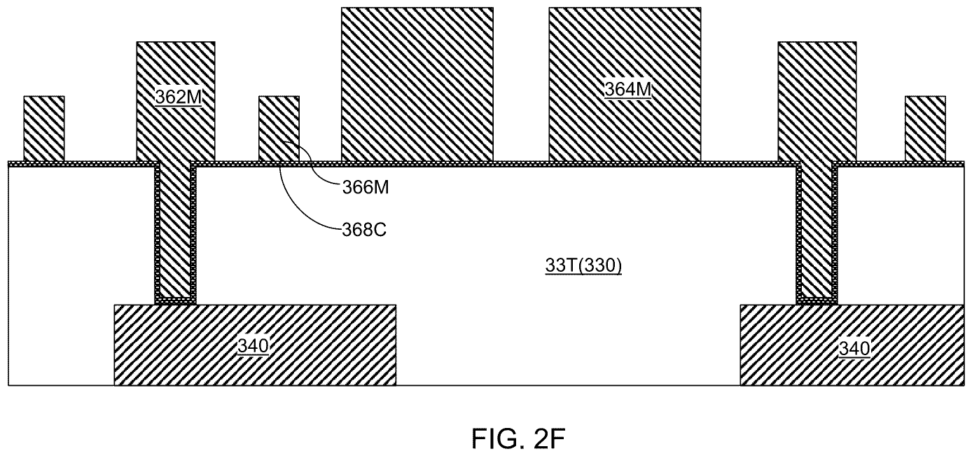

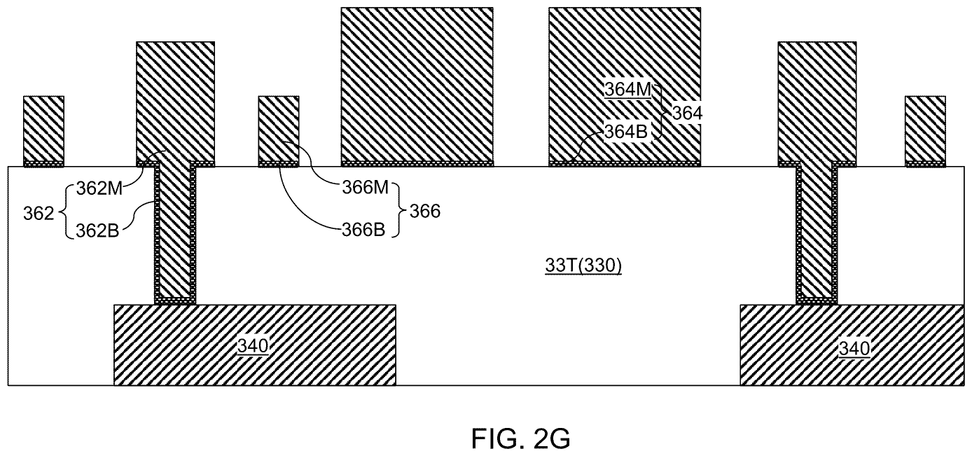

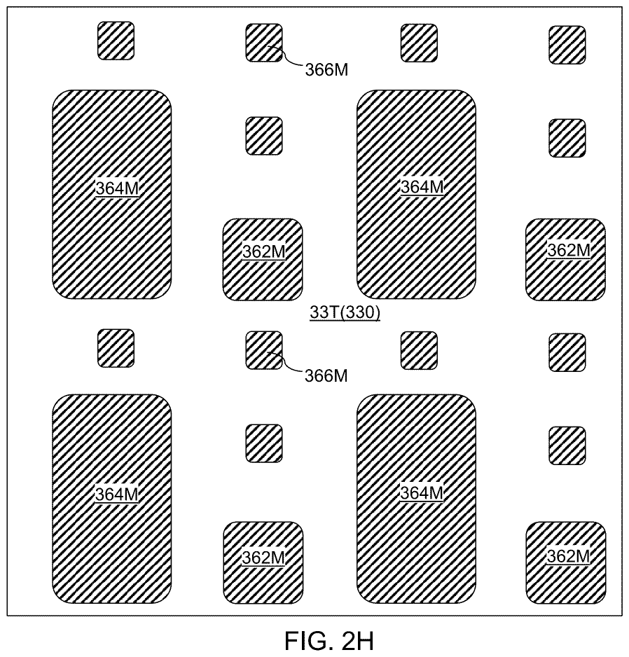

FIG. 2A-2G are sequential vertical cross-sectional views of a region of the exemplary structure during formation of active metal connection structures 362, primary dummy metal structures 364, and miniature dummy metal structures 366 according to a first embodiment of the present disclosure.

Referring to FIG. 2A, an upper region of the exemplary structure of FIG. 1 including metal interconnect structures 340 formed in the topmost dielectric material layer 33T is illustrated in a magnified view.

Referring to FIG. 2B, a photoresist layer (not shown) may be applied over the topmost dielectric material layer 33T, and may be lithographically patterned to form openings in areas that overlie a respective one of a subset of the metal interconnect structures 340 located within, or below, the topmost dielectric material layer 33T. An anisotropic etch process may be performed to form via cavities 331 through the topmost dielectric material layer 33T. Top surfaces of the subset of the metal interconnect structures 340 may be exposed underneath the via cavities 331. The photoresist layer may be subsequently removed, for example, by ashing.

Referring to FIG. 2C, a continuous metallic seed layer 368C may be deposited directly on the physically exposed surfaces of the topmost dielectric material layer 33T and directly on physically exposed top surface segments of the subset of the metal interconnect structures 340. The continuous metallic seed layer 368C functions as a conductive base layer that facilitates subsequent electroplating of copper by providing a uniform, conductive surface on which copper may be electroplated. The continuous metallic seed layer 368C may be deposited by physical vapor deposition (PVD), which may provide high conformity and thickness uniformity across the varied topography of the topmost dielectric material layer 33T and the metal interconnect structures 340. In one embodiment, the continuous metallic seed layer 368C may comprise a layer stack including a metallic barrier material layer, such as tantalum or tantalum nitride (Ta/TaN), and an overlying copper layer. The continuous metallic seed layer 368C comprises a horizontally-extending portion that overlies the horizontal top surface of the topmost dielectric material layer 33T and vertically-extending portions that protrude downward from the horizontally-extending portion into a peripheral region of a respective one of the via cavities 331. The thickness of the continuous metallic seed layer 368C may be in a range from 30 nm to 200 nm, although lesser and greater thicknesses may also be used.

Referring to FIG. 2D, a patterned electroplating mask layer 357 may be formed over the continuous metallic seed layer 368C. In one embodiment, the patterned electroplating mask layer 357 may be formed by applying a photoresist layer over the continuous metallic seed layer 368C, and by lithographically patterning the photoresist layer for form discrete openings therein. The discrete openings in the photoresist layer may comprise first-type openings 361 having an areal overlap within a respective one of the via cavities 331, second-type openings 363 not having any areal overlap with the via cavities 331 and having a respective area that is greater than any area of the first-type openings, and third-type openings 365 not having any areal overlap with the via cavities 331 and having a respective area that is less than any area of the first-type openings 361.

According to an aspect of the present disclosure, the first-type openings 361 in the patterned electroplating mask layer 357 may be formed in areas in which a first subset of bonding pads that are electrically connected to the metal interconnect structures 340 are to be subsequently formed. The second-type openings 363 in the patterned electroplating mask layer 357 may be formed in areas in which a second subset of bonding pads that are not electrically connected to the metal interconnect structures 340 are to be subsequently formed. Generally, the second-type openings 363 may fill areas of gaps selected from the first-type openings 361 as long as the second-type openings 363 may fit into the areas of gaps. The third-type openings 365 in the patterned electroplating mask layer 357 may be formed in gaps selected from the first-type openings 361 and the second-type openings 363 provided that sufficient areas are available for formation of the third-type openings 365.

In an illustrative example, the first-type openings 361 may have a respective first shape, which may be a rectangular shape or a shape of a rounded rectangle. Facing pairs of sidewalls of each first shape in a plan view (such as a top-down view) may be laterally spaced from each other by a respective first lateral dimension. Each first lateral dimension may be in a range from 5 microns to 60 microns, although lesser and greater first lateral dimensions may also be used. The second-type openings 363 may have a respective second shape, which may be a rectangular shape or a shape of a rounded rectangle. Facing pairs of sidewalls of each second shape in a plan view (such as a top-down view) may be laterally spaced from each other by a respective second lateral dimension. Each second lateral dimension may be in a range from 10 microns to 120 microns, although lesser and greater second lateral dimensions may also be used.

The third-type openings 365 may have a respective third shape, which may be a rectangular shape or a shape of a rounded rectangle. Facing pairs of sidewalls of each third shape in a plan view (such as a top-down view) may be laterally spaced from each other by a respective third lateral dimension. Each third lateral dimension may be in a range from 0.3 microns to 30 microns, such as from 1 micron to 10 microns, although lesser and greater third lateral dimensions may also be used.

Generally, a lateral dimension of each opening in the patterned electroplating mask layer 357 may be defined as a maximum lateral spacing between facing parallel pairs of sidewall segments in a plan view such as a top-down view. In instances in which a shape of an opening in a plan view is a rectangle or a rounded rectangle, the lateral dimension of the shape equals the greater of the two lateral spacings between a respective facing pair of sidewall segments of the opening in a plan view. In instances in which a shape of an opening in a plan view is a circle or an ellipse, the lateral dimension of the shape equals the diameter or the major axis of the opening in a plan view. The lateral dimensions of the second-type openings 363 may be in a range from 120% to 1,000%, such as from 200% to 500%, of the average of the lateral dimensions of the first-type openings 361. The lateral dimensions of the third-type openings 365 may be in a range from 1% to 90%, such as from 3% to 50%, of the average of the lateral dimensions of the first-type openings 361.

Referring to FIG. 2E, an electroplating process may be performed to electroplate a metallic material, which may be any electroplatable material known in the art. In one embodiment, the electroplated metallic material may consist essentially of copper. The electroplated metallic material forms electroplated material portions (362M, 364M, 366M). The electroplated material portions (362M, 364M, 366M) are formed in areas that are not masked by the patterned electroplating mask layer 357. The electroplated material portions (362M, 364M, 366M) may comprise any electroplatable metal. In one embodiment, the electroplated material portions (362M, 364M, 366M) may consist essentially of copper.

The electroplated material portions (362M, 364M, 366M) may comprise first-type electroplated material portions 362M, second-type electroplated material portions 364M having a greater height than the first-type electroplated material portions 362M, and third-type electroplated material portions 366M having a lesser height than the first-type electroplated material portions 362M. The first-type electroplated material portions 362M fill lower portions of the first-type openings 361. The second-type electroplated material portions 364M fill lower portions of the second-type openings 363. The third-type electroplated material portions 366M fill lower portions of the third-type openings 365. The first-type electroplated material portions 362M, the second-type electroplated material portions 364M, and the third-type electroplated material portions 366M are formed simultaneously in a single electroplating process.

The first height of the top surfaces of the first-type electroplated material portions 362M, as measured from the horizontal plane including the topmost surface of the continuous metallic seed layer 368C, may be in a range from 150 nm to 6,000 nm, such as from 300 nm to 3,000 nm, although lesser and greater first heights may also be used. The second height of the top surfaces of the second-type electroplated material portions 364M, as measured from the horizontal plane including the topmost surface of the continuous metallic seed layer 368C, may be in a range from 105% to 200%, such as from 110% to 150%, of the first height, although lesser and greater second heights may also be used. The third height of the top surfaces of the third-type electroplated material portions 366M, as measured from the horizontal plane including the topmost surface of the continuous metallic seed layer 368C, may be in a range from 10% to 90%, such as from 30% to 80%, of the first height, although lesser and greater third heights may also be used.

Referring to FIG. 2F, the patterned electroplating mask layer 357 may be removed by ashing or by dissolution in a solvent.

Referring to FIGS. 2G and 2H, unmasked portions of the continuous metallic seed layer 368C may be removed by performing an etch process that etches the material of the continuous metallic seed layer 368C selectively to the material of the topmost dielectric material layer 33T. In instances in which the continuous metallic seed layer 368C comprises a layer stack of a metallic barrier liner layer composed of TiN or TaN and a copper seed layer, unmasked portions of the copper seed layer and the metallic barrier liner layer may be removed by performing a two-step etch process. First, an isotropic wet etching process using a persulfate-based solution, such as ammonium persulfate, may be used to selectively remove the copper seed layer without etching the material of the metallic barrier liner layer. Subsequently, a selective dry etch process, such as reactive ion etching (RIE) using fluorine-based chemistries (e.g., CF₄ or SF₆), may be performed to remove unmasked portions of the metallic barrier liner layer. A suitable clean process may be subsequently performed to remove any residual material.

Remaining portions of the continuous metallic seed layer 368C comprise first-type metallic seed layers 362B that underlie the first-type electroplated material portions 362M, second-type metallic seed layers 364B that underlie the second-type electroplated material portions 364M, and third-type metallic seed layers 366B that underlie the third-type electroplated material portions 366M. Generally, remaining portions of the continuous metallic seed layer 368C and the electroplated material portions (362M, 364M, 366M) comprise active metal connection structures 362, primary dummy metal structures 364, and miniature dummy metal structures 366. Each active metal connection structure 362 comprises a stack of a first-type metallic seed layer 362B and a first-type electroplated material portion 362M. Each primary dummy metal structure 364 comprises a stack of a second-type metallic seed layer 364B and a second-type electroplated material portion 364M. Each miniature dummy metal structure 366 comprises a stack of a third-type metallic seed layer 366B and a third-type electroplated material portion 366M.

Thus, the active metal connection structures 362, the primary dummy metal structures 364, and the miniature dummy metal structures 366 may be formed over the topmost dielectric material layer 33T selected from the dielectric material layers 330. According to an aspect of the present disclosure, the miniature dummy metal structures 366 have a lesser height than the active metal connection structures 362 and the primary dummy metal structures 364. The first-type electroplated material portion 362M may be active electroplated material portions that are electrically connected to a respective one of the metal interconnect structures 340. The second-type electroplated material portions 364M may be first dummy electroplated material portions that are electrically isolated from the metal interconnect structures 340 and have top surfaces that are formed above a horizontal plane including top surfaces of the active electroplated material portions (i.e., the first-type electroplated material portions 362M). The third-type electroplated material portions 366M comprise second dummy electroplated material portions that are electrically isolated from the metal interconnect structures 340 and have top surfaces that are formed below the horizontal plane.

In one embodiment, each of the active metal connection structures 362 contacts a respective metal interconnect structure 340 selected from the subset of the metal interconnect structures 340. In one embodiment, the primary dummy metal structures 364 and the miniature dummy metal structures 366 do not contact any of the metal interconnect structures 340. Each of the primary dummy metal structures 364 and the miniature dummy metal structures 366 is electrically isolated from the metal interconnect structures 340. In one embodiment, each of the primary dummy metal structures 364 is electrically isolated from the active metal connection structures 362, the miniature dummy metal structures 366, and any other primary dummy metal structure 364. In one embodiment, each of the miniature dummy metal structures 366 is electrically isolated from the active metal connection structures 362, the primary dummy metal structures 364, and any other miniature dummy metal structure 366.

The miniature dummy metal structures 366 have a lesser height than the active metal connection structures 362 and the primary dummy metal structures 364. The primary dummy metal structures 364 have a greater height than the active metal connection structures 362 and the miniature dummy metal structures 366. Each of the primary dummy metal structures 364 and the miniature dummy metal structures 366 is formed entirely in a region in which via cavities 331 are absent.

Each of the active metal connection structures 362 comprises a respective via portion that vertically extends through the topmost dielectric material layer 33T and contacts a respective one of the metal interconnect structures 340. In one embodiment, each of the primary dummy metal structures 364 and the miniature dummy metal structures 366 is formed entirely above a horizontal plane including a top surface of the topmost dielectric material layer 33T. In one embodiment, each of the active metal connection structures 362, the primary dummy metal structures 364, and the miniature dummy metal structures 366 comprises a respective bottom surface located within a horizontal plane including a top surface of the topmost dielectric material layer 33T. In one embodiment, each of the active metal connection structures 362 contacts a respective one of the metal interconnect structures 340, and the primary dummy metal structures 364 and the miniature dummy metal structures 366 do not contact any of the metal interconnect structures 340.

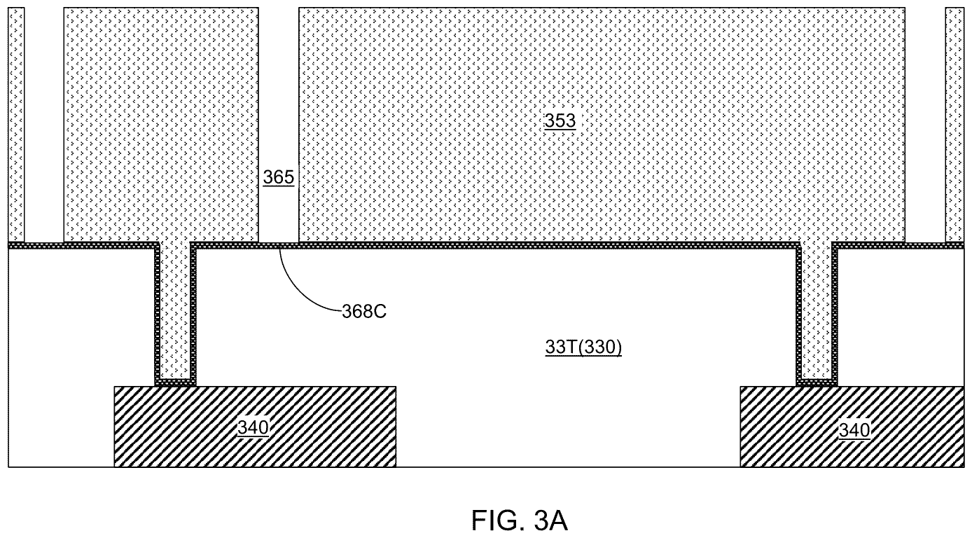

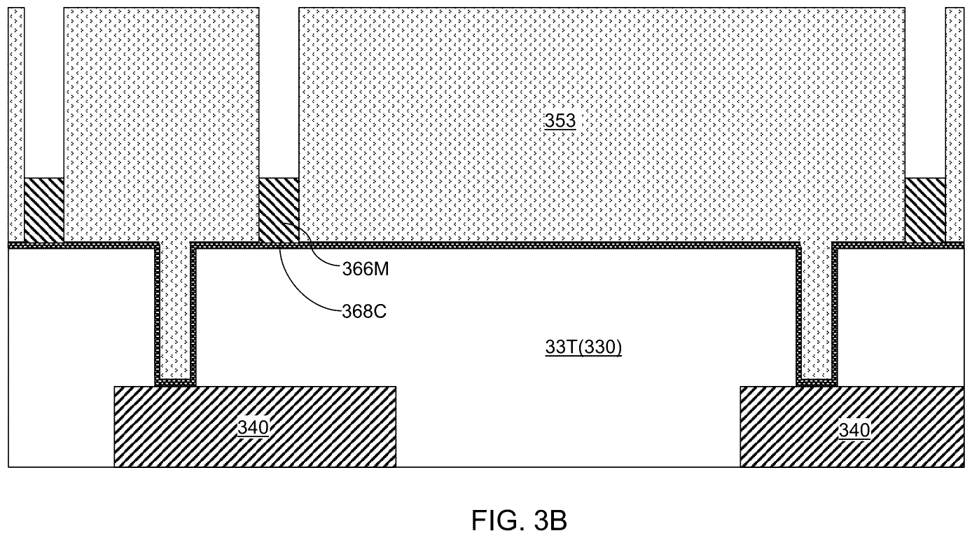

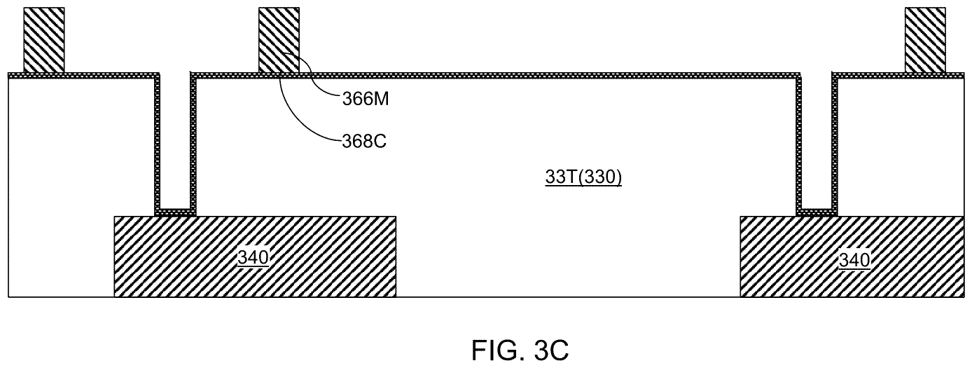

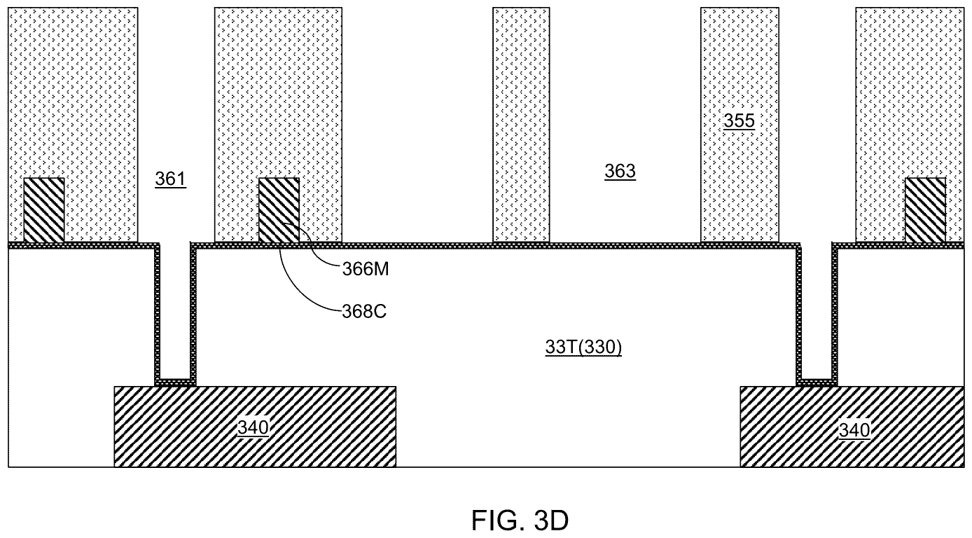

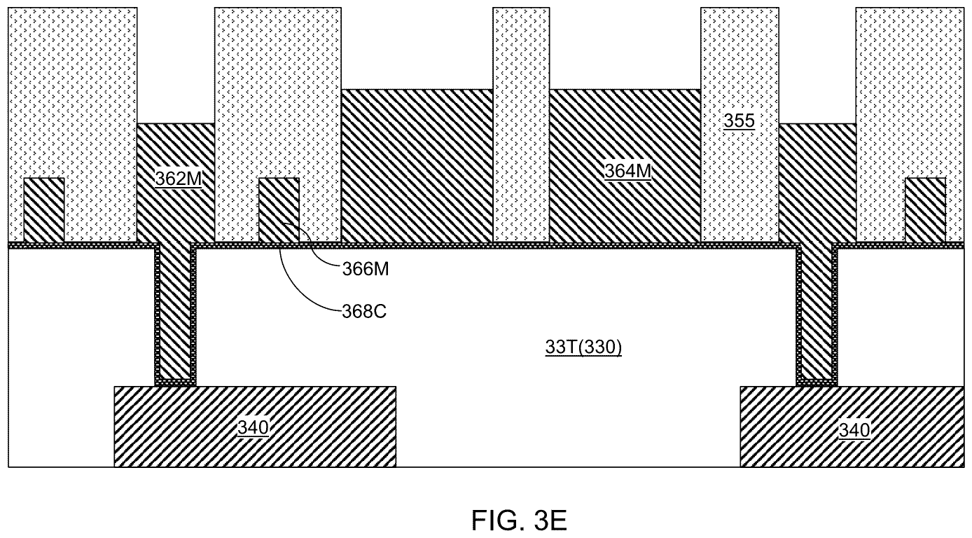

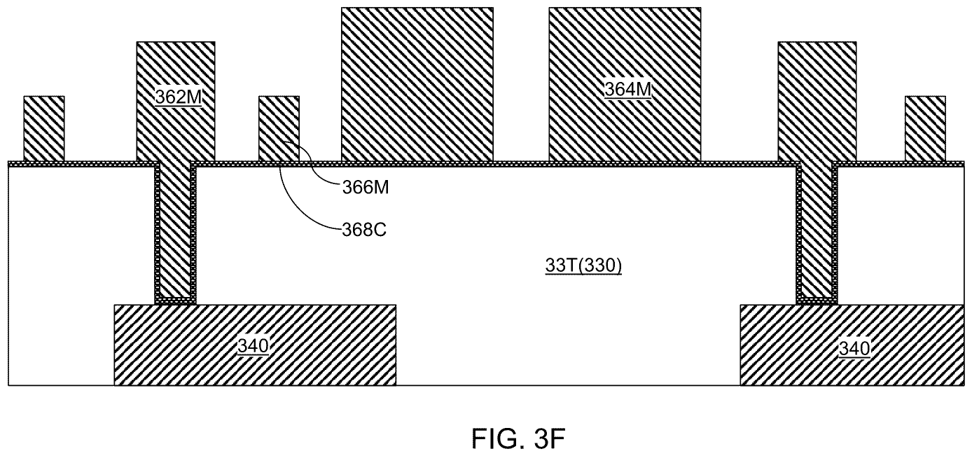

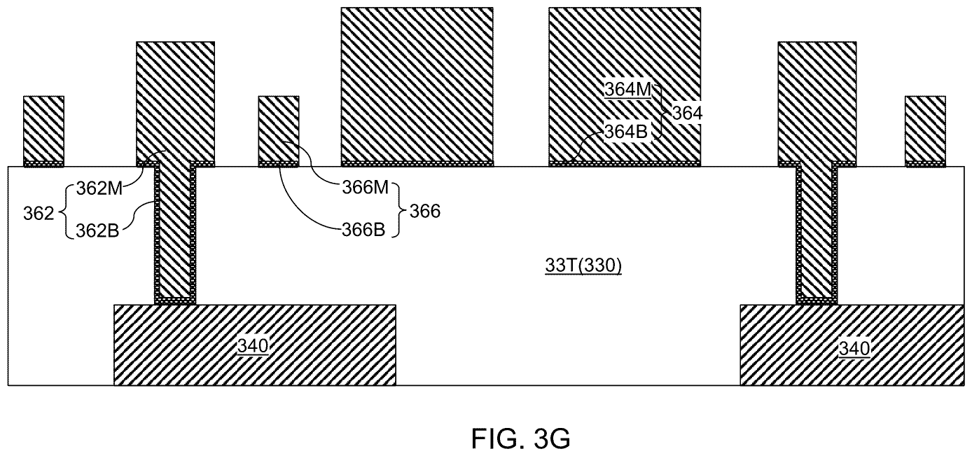

FIG. 3A-3G are sequential vertical cross-sectional views of a region of the exemplary structure during formation of active metal connection structures 362, primary dummy metal structures 364, and miniature dummy metal structures 366 according to a second embodiment of the present disclosure.

Referring to FIG. 3A, a region of the exemplary structure is illustrated after formation of a first patterned electroplating mask layer 353. The exemplary structure illustrated in FIG. 3A may be derived from the exemplary structure illustrated in FIG. 2C by forming the first patterned electroplating mask layer 353. The pattern of openings in the first patterned electroplating mask layer 353 may be the same as the pattern of the third-type openings 365 in the patterned electroplating mask layer 357 described with reference to FIG. 2D. Thus, the first patterned electroplating mask layer 353 do not include the pattern of the first-type openings 361 or the pattern of the second-type openings 363 that are present in the patterned electroplating mask layer 357 described with reference to FIG. 2D.

Referring to FIG. 3B, a first electroplating process may be performed to a electroplate a first metallic material, which may be any electroplatable material known in the art. In one embodiment, the first electroplated metallic material may consist essentially of copper. In one embodiment, the first electroplated metallic material may consist essentially of copper. Alternatively, the first electroplated metallic material may comprise a non-copper electroplatable material such as nickel, silver, gold, zinc, cobalt-tungsten (CoW), or cobalt-tungsten-phosphorus (CoWP). In one embodiment, the first metallic material may be selected to provide different levels of susceptibility to deformation relative to copper to be used for active metal connection structures to be subsequently formed. Copper has a relatively low yield strength, typically around 70-100 MPa, indicating moderate susceptibility to deformation under stress. In contrast, the yield strength of nickel, silver, gold, zinc, CoW, and CoWP is approximately 150-300 MPa, 50-150 MPa, 200-250 MPa, 50-100 MPa, 400-600 MPa, and 400-600 MPa, respectively, indicating varying levels of resistance to deformation. The first electroplated material forms electroplated material portions, which are herein referred to as third-type electroplated material portions 366M. The height of the top surfaces of the third-type electroplated material portions 366M, as measured from the horizontal plane including the topmost surface of the continuous metallic seed layer 368C, may be in a range from 50 nm to 3,000 nm, such as from 100 nm to 1,500 nm, although lesser and greater heights may also be used.

Referring to FIG. 3C, the first patterned electroplating mask layer 353 may be removed by ashing or by dissolution in a solvent.

Referring to FIG. 3D, a second patterned electroplating mask layer 355 may be formed over the continuous metallic seed layer 368C and the third-type electroplated material portions 366M. The pattern of openings in the second patterned electroplating mask layer 355 may be the same as the pattern of first-type openings 361 and second-type openings 363 in the patterned electroplating mask layer 357 described with reference to FIG. 2D. Thus, the pattern of the openings in the second patterned electroplating mask layer 355 may be derived from the pattern of the openings in the patterned electroplating mask layer 357 described with reference to FIG. 2D by omitting the pattern of the third-type openings 365. Each of the third-type electroplated material portions 366M may be covered by the second patterned electroplating mask layer 355.

Referring to FIG. 3E, a second electroplating process may be performed to a electroplate a second metallic material. In one embodiment, the second electroplated metallic material may consist essentially of copper. First-type electroplated material portions 362M are formed in the first-type openings, and second-type electroplated material portions 364M are formed in the second-type openings. Thus, the first-type electroplated material portions 362M, the second-type electroplated material portions 364M, and the third-type electroplated material portions 366M are formed using a plurality of electroplating processes.

The first height of the top surfaces of the first-type electroplated material portions 362M, as measured from the horizontal plane including the topmost surface of the continuous metallic seed layer 368C, may be in a range from 150 nm to 6,000 nm, such as from 300 nm to 3,000 nm, although lesser and greater first heights may also be used. The second height of the top surfaces of the second-type electroplated material portions 364M, as measured from the horizontal plane including the topmost surface of the continuous metallic seed layer 368C, may be in a range from 105% to 200%, such as from 110% to 150%, of the first height, although lesser and greater second heights may also be used. The third height of the top surfaces of the third-type electroplated material portions 366M, as measured from the horizontal plane including the topmost surface of the continuous metallic seed layer 368C, may be in a range from 10% to 90%, such as from 30% to 80%, of the first height, although lesser and greater third heights may also be used.

Referring to FIG. 3F, the second patterned electroplating mask layer 355 may be removed by ashing or by dissolution in a solvent.

Referring to FIG. 3G, unmasked portions of the continuous metallic seed layer 368C may be removed by performing an etch process that etches the material of the continuous metallic seed layer 368C selectively to the material of the topmost dielectric material layer 33T. If the continuous metallic seed layer 368C comprises a layer stack of a metallic barrier liner layer composed of TiN or TaN and a copper seed layer, unmasked portions of the copper seed layer and the metallic barrier liner layer may be removed by performing a two-step etch process. First, an isotropic wet etching process using a persulfate-based solution, such as ammonium persulfate, may be used to selectively remove the copper seed layer without etching the material of the metallic barrier liner layer. Subsequently, a selective dry etch process, such as reactive ion etching (RIE) using fluorine-based chemistries (e.g., CF₄ or SF₆), may be performed to remove unmasked portions of the metallic barrier liner layer. A suitable clean process may be subsequently performed to remove any residual material.

Remaining portions of the continuous metallic seed layer 368C comprise first-type metallic seed layers 362B that underlie the first-type electroplated material portions 362M, second-type metallic seed layers 364B that underlie the second-type electroplated material portions 364M, and third-type metallic seed layers 366B that underlie the third-type electroplated material portions 366M. Generally, remaining portions of the continuous metallic seed layer 368C and the electroplated material portions (362M, 364M, 366M) comprise active metal connection structures 362, primary dummy metal structures 364, and miniature dummy metal structures 366. Each active metal connection structure 362 comprises a stack of a first-type metallic seed layer 362B and a first-type electroplated material portion 362M. Each primary dummy metal structure 364 comprises a stack of a second-type metallic seed layer 364B and a second-type electroplated material portion 364M. Each miniature dummy metal structure 366 comprises a stack of a third-type metallic seed layer 366B and a third-type electroplated material portion 366M.

Thus, the active metal connection structures 362, the primary dummy metal structures 364, and the miniature dummy metal structures 366 may be formed over the topmost dielectric material layer 33T selected from the dielectric material layers 330. According to an aspect of the present disclosure, the miniature dummy metal structures 366 have a lesser height than the active metal connection structures 362 and the primary dummy metal structures 364. The first-type electroplated material portion 362M may be active electroplated material portions that are electrically connected to a respective one of the metal interconnect structures 340. The second-type electroplated material portions 364M may be first dummy electroplated material portions that are electrically isolated from the metal interconnect structures 340 and have top surfaces that are formed above a horizontal plane including top surfaces of the active electroplated material portions (i.e., the first-type electroplated material portions 362M). The third-type electroplated material portions 366M comprise second dummy electroplated material portions that are electrically isolated from the metal interconnect structures 340 and have top surfaces that are formed below the horizontal plane.

In one embodiment, each of the active metal connection structures 362 contacts a respective metal interconnect structure 340 selected from the subset of the metal interconnect structures 340. In one embodiment, the primary dummy metal structures 364 and the miniature dummy metal structures 366 do not contact any of the metal interconnect structures 340. Each of the primary dummy metal structures 364 and the miniature dummy metal structures 366 is electrically isolated from the metal interconnect structures 340. In one embodiment, each of the primary dummy metal structures 364 is electrically isolated from the active metal connection structures 362, the miniature dummy metal structures 366, and any other primary dummy metal structure 364. In one embodiment, each of the miniature dummy metal structures 366 is electrically isolated from the active metal connection structures 362, the primary dummy metal structures 364, and any other miniature dummy metal structure 366.

The miniature dummy metal structures 366 have a lesser height than the active metal connection structures 362 and the primary dummy metal structures 364. The primary dummy metal structures 364 have a greater height than the active metal connection structures 362 and the miniature dummy metal structures 366. Each of the primary dummy metal structures 364 and the miniature dummy metal structures 366 is formed entirely in a region in which via cavities 331 are absent.

Each of the active metal connection structures 362 comprises a respective via portion that vertically extends through the topmost dielectric material layer 33T and contacts a respective one of the metal interconnect structures 340. In one embodiment, each of the primary dummy metal structures 364 and the miniature dummy metal structures 366 is formed entirely above a horizontal plane including a top surface of the topmost dielectric material layer 33T. In one embodiment, each of the active metal connection structures 362, the primary dummy metal structures 364, and the miniature dummy metal structures 366 comprises a respective bottom surface located within a horizontal plane including a top surface of the topmost dielectric material layer 33T. In one embodiment, each of the active metal connection structures 362 contacts a respective one of the metal interconnect structures 340, and the primary dummy metal structures 364 and the miniature dummy metal structures 366 do not contact any of the metal interconnect structures 340.

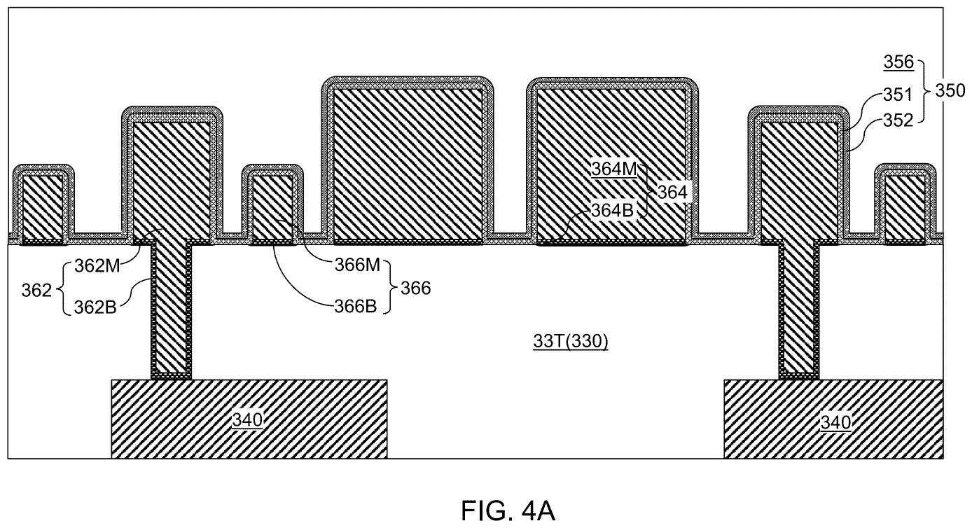

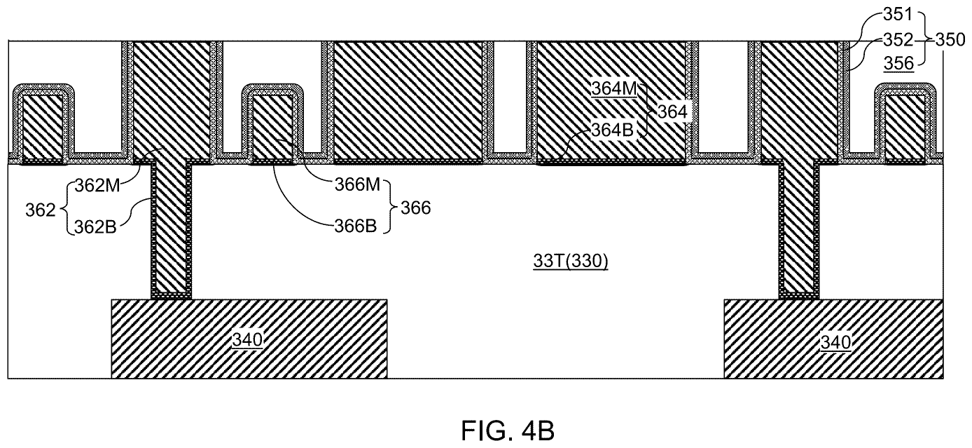

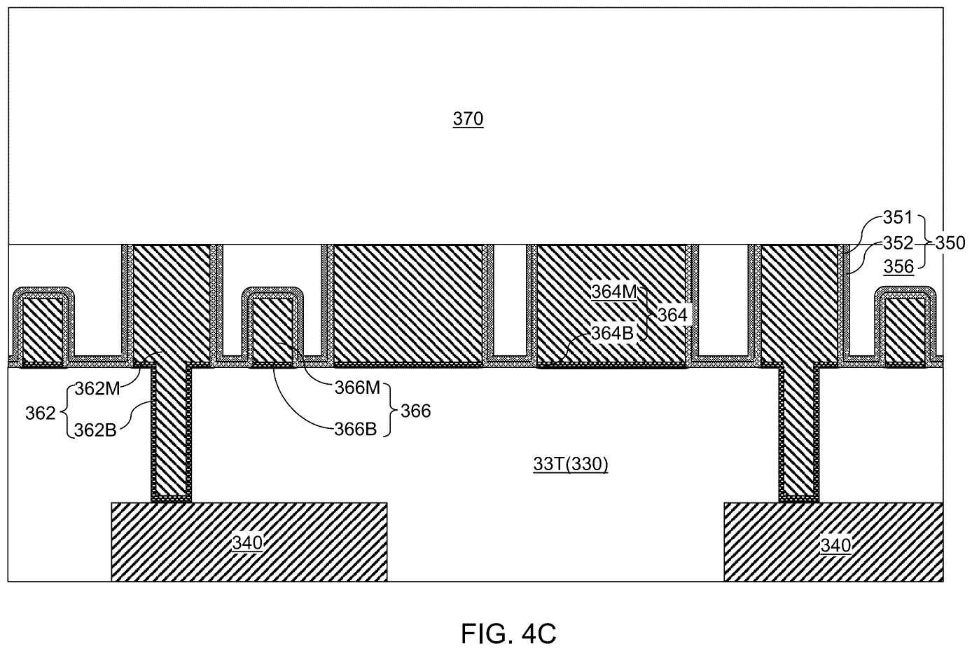

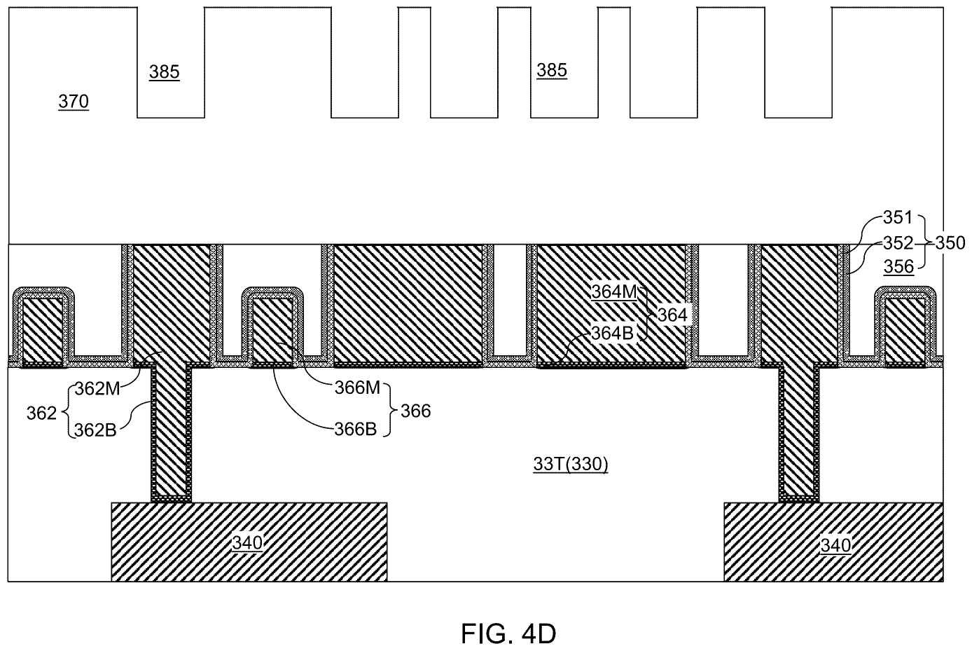

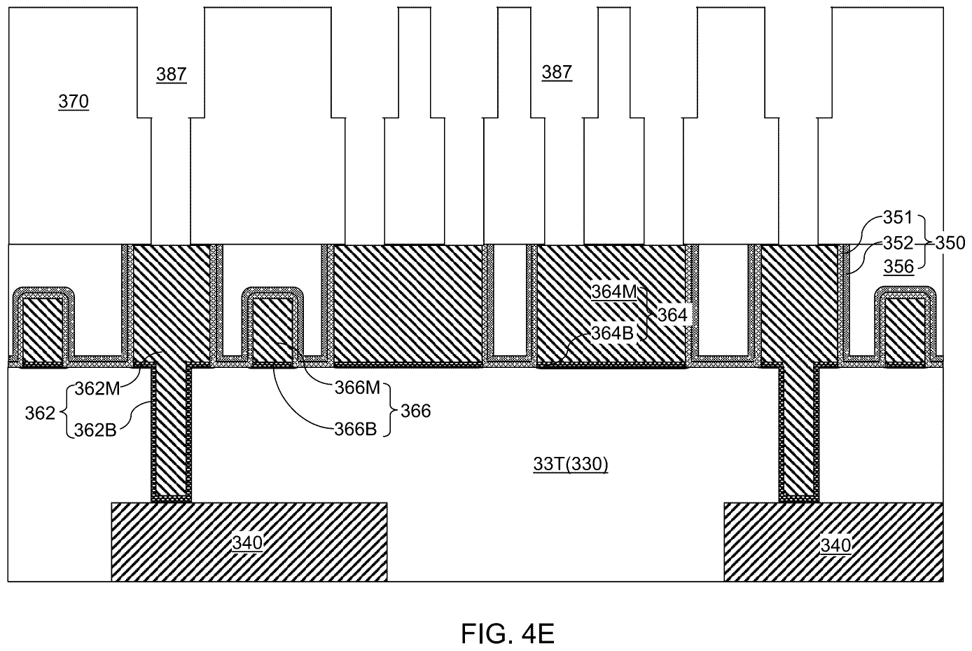

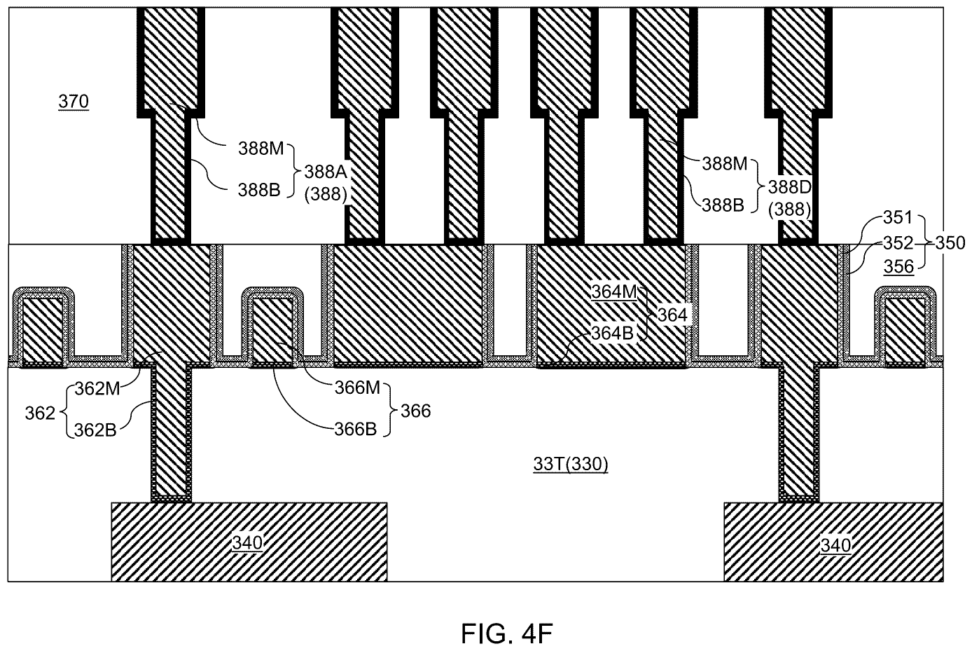

FIG. 4A-4F are sequential vertical cross-sectional views of a region of the exemplary structure during planarization of the active metal connection structures 362, the primary dummy metal structures 364, and the miniature dummy metal structures 366 and formation of bonding pads 388 according to an embodiment of the present disclosure.

Referring to FIG. 4A, a connection-level dielectric layer 350 may be formed over the active metal connection structures 362, the primary dummy metal structures 364, and the miniature dummy metal structures 366. In one embodiment, the connection-level dielectric layer 350 may comprise at least one connection-level passivation dielectric layer (351, 352) and a connection-level planarization dielectric layer 356. The at least one connection-level passivation dielectric layer (351, 352) may comprise a layer stack of a first connection-level passivation dielectric layer 351 and a second connection-level passivation dielectric layer 352. In an illustrative example, the first connection-level passivation dielectric layer 351 may comprise a silicon nitride layer having a thickness in a range from 10 nm to 200 nm, and the second connection-level passivation dielectric layer 352 may comprise a silicon carbide nitride layer having a thickness in a range from 10 nm to 200 nm, although lesser and greater thicknesses may also be used for each of the first connection-level passivation dielectric layer 351 and the second connection-level passivation dielectric layer 352. The connection-level planarization dielectric layer 356 comprises planarizable dielectric material such as a silicate glass material. The thickness of a portion of the connection-level planarization dielectric layer 356 that overlies the primary dummy metal structures 364 may be in a range from 300 nm to 6,000 nm, such as from 600 nm to 3,000 nm, although lesser and greater thicknesses may also be used.

Referring to FIG. 4B, a planarization process such as a chemical mechanical polishing (CMP) process may be performed to remove portions of the connection-level dielectric layer 350, the active metal connection structures 362, and the primary dummy metal structures 364 that overlie a horizontal plane. The horizontal plane may be located above the horizontal plane including top surfaces of the miniature dummy metal structures 366, and may be located below the horizontal plane including top surfaces of the primary dummy metal structures 364. Top surfaces of the active metal connection structures 362 and the primary dummy metal structures 364 may be formed within the same horizontal plane including the top surface of the planarized connection-level dielectric layer 350. The connection-level dielectric layer 350 may laterally surround the active metal connection structures 362, the primary dummy metal structures 364, and the miniature dummy metal structures 366. The top surfaces of the active metal connection structures 362 and the primary dummy metal structures 364 are physically exposed at the horizontal plane including the top surface of the connection-level dielectric layer 350. Top surfaces of the miniature dummy metal structures 366 are located below the horizontal plane, and thus, are not physically exposed.

Referring to FIG. 4C, a bonding-level dielectric layer 370 may be formed over the connection-level dielectric layer 350, the active metal connection structures 362, the primary dummy metal structures 364, and the miniature dummy metal structures 366. The bonding-level dielectric layer 370 may comprise a dielectric material that may be used for dielectric-to-dielectric bonding. In one embodiment, the bonding-level dielectric layer 370 comprises a silicate glass material such as undoped silicate glass or a doped silicate glass. The thickness of the bonding-level dielectric layer 370 may be in a range from 1 micron to 15 microns, such as from 3 microns to 8 microns, although lesser and greater thicknesses may also be used.

Referring to FIG. 4D, a first photoresist layer (not shown) may be applied over the bonding-level dielectric layer 370, and may be lithographically patterned to form first discrete openings overlying the active metal connection structures 362 and the primary dummy metal structures 364. Each first discrete opening may have a respective shape of a rectangle, a rounded rectangle, a circle, or an ellipse. An anisotropic etch process may be performed to transfer the pattern of the first discrete openings in the photoresist layer into an upper portion of the bonding-level dielectric layer 370. Plate-shaped cavities 385 may be formed in an upper portion of the bonding-level dielectric layer 370. The first photoresist layer may be subsequently removed, for example, by ashing.

Referring to FIG. 4E, a second photoresist layer (not shown) may be applied over the bonding-level dielectric layer 370, and may be lithographically patterned to form second discrete openings. Each of the second discrete openings may have an areal overlap with a respective one of the plate-shaped cavities 385 and with a respective one of the active metal connection structures 362 and the primary dummy metal structures 364. An anisotropic etch process may be performed to etch lower portions of the bonding-level dielectric layer 370 that are not masked by the first photoresist layer. Via cavities are formed underneath the plate-shaped cavities 385 such that top surface segments of the active metal connection structures 362 and the primary dummy metal structures 364 are physically exposed underneath the via cavities. The second photoresist layer may be subsequently removed, for example, by ashing. Each contiguous combination of a plate-shaped cavity 385 and at least one underlying via cavity constitutes a pad cavity 387. Generally, the pad cavities 387 may be formed through the bonding-level dielectric layer 370 such that top surface segments of the active metal connection structures 362 and the primary dummy metal structures 364 are exposed under the pad cavities 387.

Referring to FIG. 4F, a metallic barrier liner layer including a conductive metallic nitride material (such as TiN, TaN, WN, and/or MoN) and at least one metallic fill material that may be used for metal-to-metal bonding (such as copper) may be deposited in the pad cavities 387. Excess portions of the metallic barrier liner layer and the at least one metallic fill material may be removed from above the horizontal plane including the top surface of the bonding-level dielectric layer 370 by performing a planarization process such as a chemical mechanical polishing process. Each remaining portion of the metallic barrier liner layer and the at least one metallic fill material constitutes a bonding pad 388. Each bonding pad 388 may comprise a respective combination of a metallic barrier liner 388B and metallic fill material portion 388M. In one embodiment, each metallic fill material portion 388M may comprise a copper portion. The bonding pads 388 comprise active bonding pads 388A that are formed on the active metal connection structures 362, and dummy bonding pads 388D that are formed on the primary dummy metal structures 364.

Generally, the bonding pads 388 may be formed over the active metal connection structures 362, the primary dummy metal structures 364, and the miniature dummy metal structures 366. The active metal connection structures 362 and the primary dummy metal structures 364 are contacted by the bonding pads 388. The miniature dummy metal structures 366 are not contacted by any of the bonding pads 388. Each of the miniature dummy metal structures 366 may be electrically isolated from the metal interconnect structures 340, the bonding pads 388, the active metal connection structures 362, and the primary dummy metal structures 364. Each of the primary dummy metal structures 364 is electrically isolated from the metal interconnect structures 340 and the active metal connection structures 362, and contacts a respective bonding pads 388.

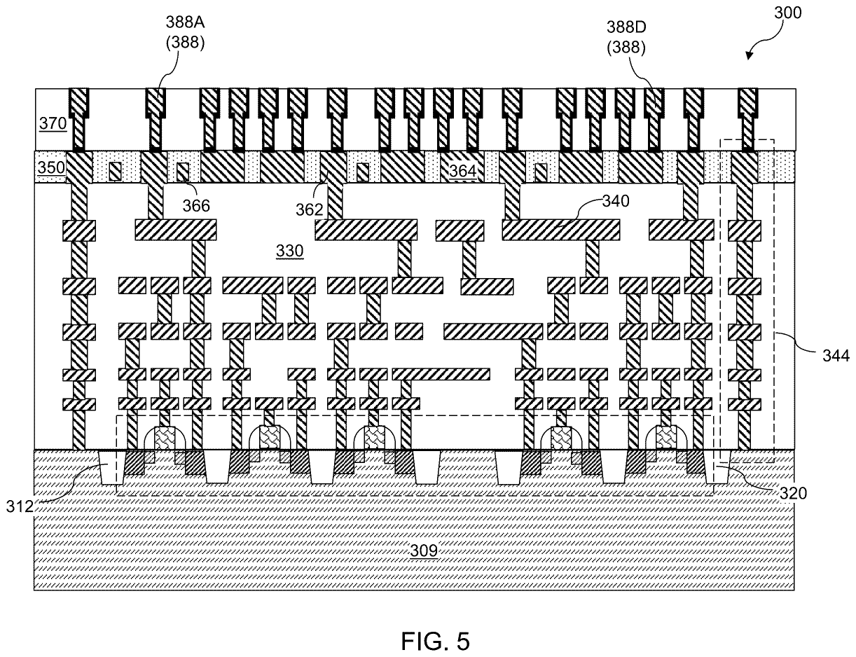

Referring to FIG. 5, the exemplary structure is illustrated after formation of the bonding pads 388. In one embodiment, the semiconductor substrate 309 may be provided as a semiconductor wafer, and a plurality of semiconductor dies 300 may be formed over the semiconductor wafer. In this embodiment, a dicing process may be performed to singulate the plurality of semiconductor dies 300.

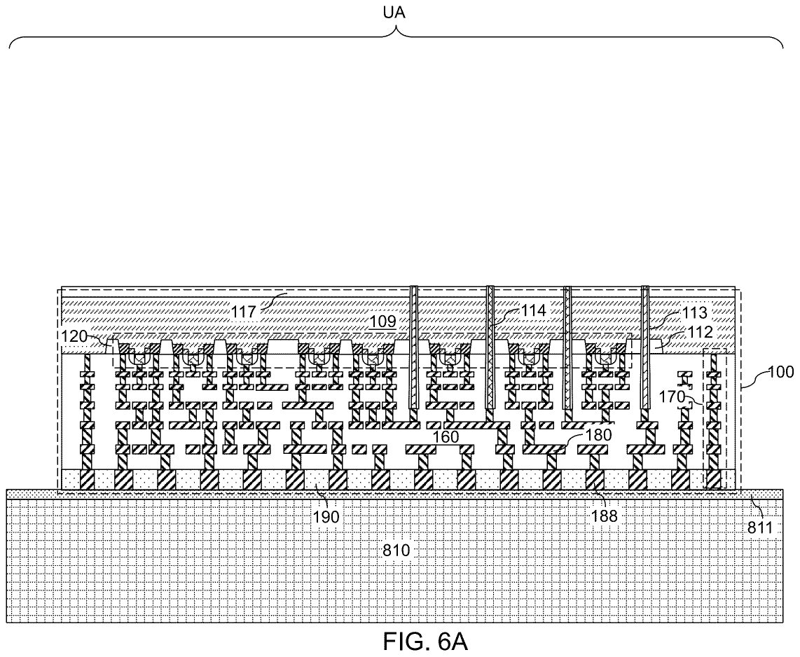

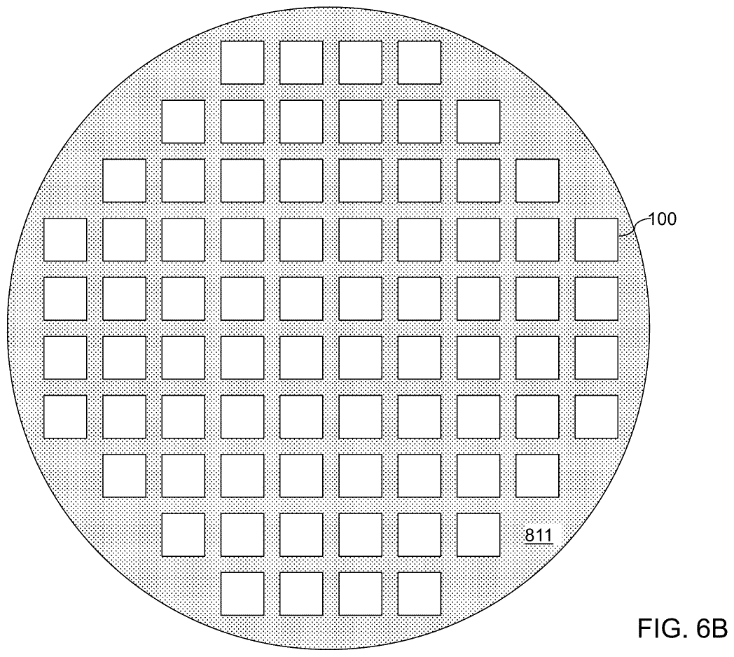

Referring to FIGS. 6A and 6B, a reconstituted wafer including a carrier substrate 810 and a two-dimensional array of first semiconductor dies 100 is illustrated. The carrier substrate 810 may be any type of carrier substrate that is suitable for carrying an array of semiconductor dies thereupon. For example, the carrier substrate 810 may be a glass substrate, a semiconductor substrate, or a conductive substrate. As shown in FIG. 6B, the carrier substrate 810 may have a circular shape in a plan view. In other embodiments (not shown), the carrier substrate may have a rectangular shape, or any other shape that is suitable for carrying an array of semiconductor dies thereupon. The first semiconductor dies 100 may be any type of semiconductor dies known in the art. For example, the first semiconductor dies 100 may comprise logic dies including at least one central processing unit (CPU), at least one graphic processing unit (GPU), at least one neural processing unit (NPU), at least one memory array, and/or any other type of semiconductor devices known in the art. The array of the first semiconductor dies 100 may be attached to the carrier substrate 810 using an adhesive layer 811. The array of the first semiconductor dies 100 may be arranged as a periodic two-dimensional array. The area that constitutes a minimum unit of repetition within the periodic two-dimensional array is herein referred to as unit area.

In one embodiment, each first semiconductor die 100 may be attached to the carrier substrate 810 through an adhesive layer 811, which may be a thermally-decomposable adhesive layer such as a polyimide layer, or may be an ultraviolet-decomposable adhesive layer such as an ultraviolet-sensitive tape. The first semiconductor die 100 may comprise a first semiconductor substrate 109, first semiconductor devices 120 located on the first semiconductor substrate 109, first metal interconnect structures 180 formed within first dielectric material layers 160, a first bonding-level dielectric layer 190, and package bonding structures 188 formed within the first bonding-level dielectric layer 190. The package bonding structures 188 function as bonding structures of the composite die to be subsequently formed, and may be configured for solder-mediated bonding (such as chip connection bonding, i.e., microbump bonding, or controlled collapse chip connection bonding, i.e., C4 bonding) or may be configured for metal-to-metal bonding. A first-die edge seal ring structure 170 may vertically extend through the first dielectric material layers 160 and the first bonding-level dielectric layer 190, and may laterally surround the entirety of the first metal interconnect structures 180.

The first semiconductor devices 120 may comprise any semiconductor device known in the art such as field effect transistors and passive devices. First shallow trench isolation structures 112 may be provided within the first semiconductor substrate 109 such that neighboring pairs of first semiconductor devices 120 may be electrically isolated from each other. The first semiconductor die 100 may comprise through-substrate via (TSV) structures 114 which vertically extends through the first semiconductor substrate 109 and optionally through a subset of the first dielectric material layers 160. The TSV structures 114 may be electrically isolated from the first semiconductor substrate 109 by dielectric liners 113. A first backside dielectric layer 117 may be provided on the backside of the first semiconductor substrate 109. In this embodiment, the TSV structures 114 may vertically extend through the first backside dielectric layer 117. In one embodiment, the TSV structures 114 may be arranged in a periodic pattern having a same periodicity as the pattern of first active bonding pads to be subsequently formed over the first backside dielectric layer 117. Each of the sidewalls of the first semiconductor die 100 may be physically exposed.

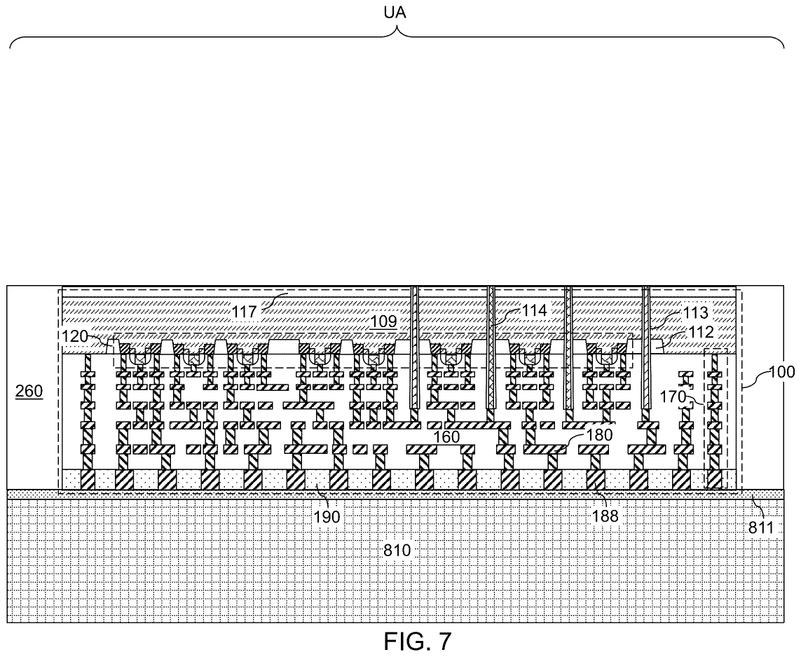

Referring to FIG. 7, a first molding compound may be applied to the gaps between neighboring pairs of the first semiconductor dies 100. The first molding compound may include an epoxy-containing compound that may be hardened (i.e., cured) to provide a dielectric material portion having sufficient stiffness and mechanical strength. The first molding compound may include epoxy resin, hardener, silica (as a filler material), and other additives. The first molding compound may be provided in a liquid form or in a solid form depending on the viscosity and flowability. Liquid first molding compound provides better handling, good flowability, less voids, better fill, and less flow marks. Solid molding compound provides less cure shrinkage, better stand-off, and less die drift. A high filler content (such as 85% in weight) within a molding compound may shorten the time in mold, lower the mold shrinkage, and reduce the mold warpage. Uniform filler size distribution in the molding compound may reduce flow marks, and may enhance flowability. The curing temperature of the molding compound may be lower than the release (debonding) temperature of the adhesive layer 811 in embodiments in which the adhesive layer 811 includes a thermally debonding material. For example, the curing temperature of the first molding compound may be in a range from 125° C. to 150° C.

The first molding compound may be cured at a curing temperature to form a first molding compound matrix 260 that laterally surrounds the two-dimensional array of the first semiconductor dies 100. The first molding compound matrix 260 comprise a plurality of first molding compound die frames that are interconnected to one another. Each first molding compound die frame is a portion of the first molding compound matrix 260 that is located within an area of a repetition unit within a two-dimensional periodic array of structures overlying the carrier substrate 810. Thus, each first molding compound die frame laterally surrounds and embeds a respective first semiconductor die 100.

Portions of the first molding compound matrix 260 that overlie the horizontal plane including the top surfaces of the first semiconductor dies 100 may be removed by a planarization process. For example, the portions of the first molding compound matrix 260 that overlie the horizontal plane may be removed using a chemical mechanical planarization (CMP). The combination of the remaining portion of the first molding compound matrix 260 and the array of first semiconductor dies 100 comprises a reconstituted wafer. Each portion of the first molding compound matrix 260 located within a unit area constitutes a first molding compound die frame. Generally, a first molding compound matrix 260 may be formed around a first semiconductor die 100 such that a top surface of the first molding compound matrix 260 is coplanar with a top dielectric surface of the first semiconductor die 100.

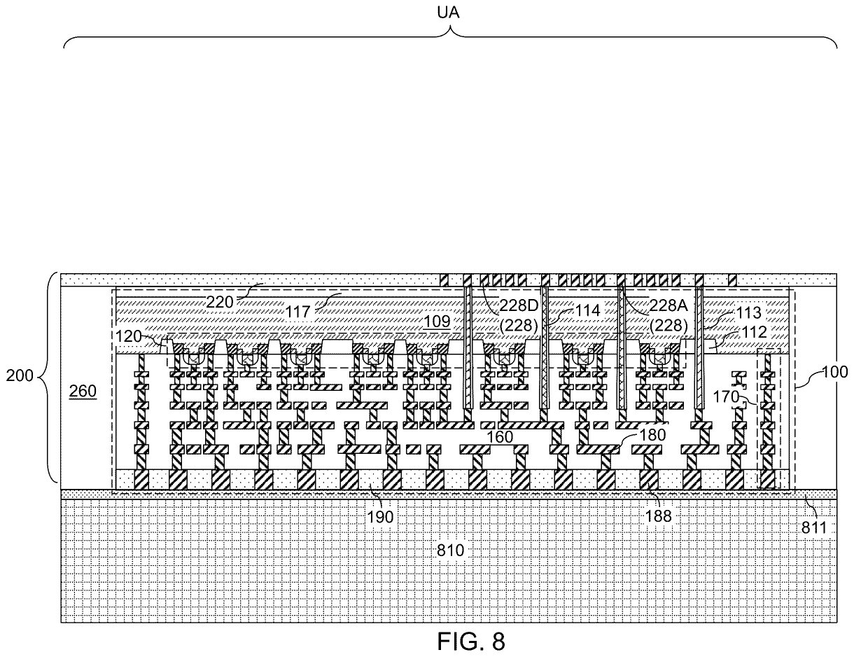

Referring to FIG. 8, a combination of at least one bonding-level dielectric layer 220 and first bonding pads 228 may be formed over the first semiconductor die 100 and the first molding compound matrix 260. The first bonding pads 228 may comprise first active bonding pads 228A that are electrically connected to the a respective one of the first metal interconnect structures 180, and may further comprise first dummy bonding pads 228D that are not electrically connected to any other conductive structure. Each of the first active bonding pads 228A may be formed directly on a respective conductive structure (such as a through-substrate via structure 114) within the first semiconductor die 100. Each portion of the exemplary structure within a unit area is herein referred to as a first molded die unit 200, which includes a first die set of a first semiconductor die 100 and portions of the first molding compound matrix 260 and the combination of the at least one bonding-level dielectric layer 220, first active bonding pads 228A, and first dummy bonding pads 228D that are located within a unit area.

Generally, each of the first dummy bonding pads 228D may have the same material composition as, or may have a different material composition than, the first active bonding pads 228A. In one embodiment, all of the first dummy bonding pads 228D may have the same material composition as the first active bonding pads 228A. In another embodiment, all of the first dummy bonding pads 228D may have a different material composition than the first active bonding pads 228A. The at least one bonding-level dielectric layer 220 may comprise a single bonding-level dielectric layer 220, or may comprise a plurality of bonding-level dielectric layers 220.

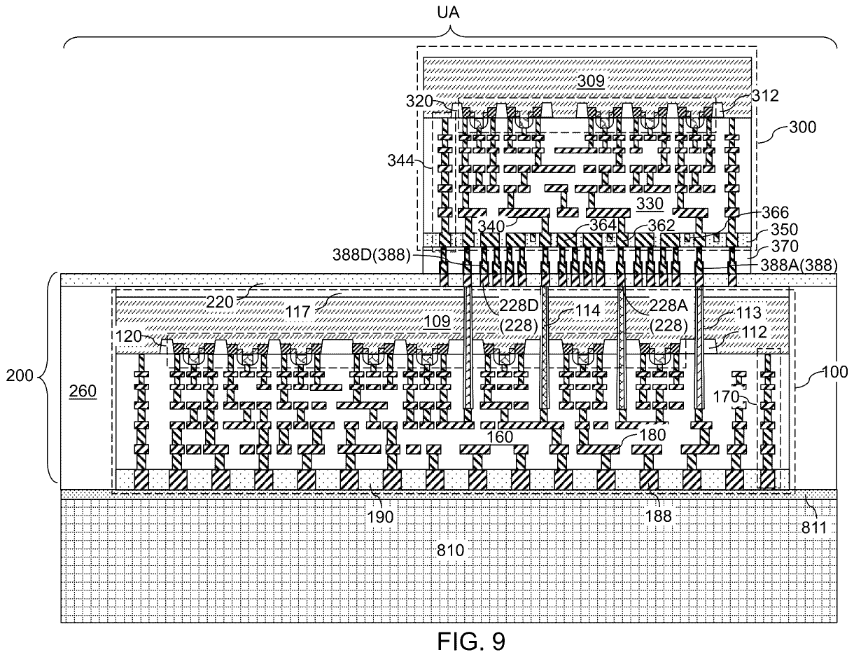

Referring to FIG. 9, second semiconductor dies 300 having second bonding pads 388 may be bonded to a respective one of the first semiconductor dies 100 by metal-to-metal bonding. The second semiconductor die 300 may be the same as the semiconductor die 300 described with reference to FIG. 5 and formed using the processing steps described with reference to FIG. 1-4F. The bonding pads 388 of the second semiconductor die 300 are hereafter referred to as second bonding pads 388. Generally, each structural element in the second semiconductor die 300 may be hereafter referred to as a second structural element in embodiments in which a similar structural element is present in the first semiconductor dies 100.

A plurality of second semiconductor dies 300 may be bonded to a plurality of first semiconductor dies 100. Each second semiconductor die 300 may be bonded to a respective first semiconductor die 100 by performing a bonding process that bonds the second bonding pads 388 of the second semiconductor die 300 to the first bonding pads 228 within a respective unit area containing the first semiconductor die 100 by metal-to-metal bonding. In one embodiment, the first active bonding pads 228A may be bonded to the second active bonding pads 388A, and the first dummy bonding pads 228D may be bonded to the second dummy bonding pads 388D.

Each second semiconductor die 300 may comprise a second semiconductor substrate 309, second semiconductor devices 320 located on the second semiconductor substrate 309, second metal interconnect structures 340 formed within second dielectric material layers 330, a second bonding-level dielectric layer 370, and second bonding pads 388 formed within the second bonding-level dielectric layer 370. The second bonding pads 388 may be configured for metal-to-metal bonding such as copper-to-copper bonding. As used herein, metal-to-metal bonding refers to the direct bonding of metal surfaces without the use of intermediate adhesives or solders. Metal-to-metal bonding may be provided through thermocompression bonding and/or diffusion bonding between two metallic surfaces that are in direct contact with each other by performing an anneal process at an elevated temperature.

A second-die edge seal ring structure 344 (which may also be referred to as an edge seal ring structure 344) may vertically extend through the second dielectric material layers 330 and the second bonding-level dielectric layer 350, and may laterally surround the entirety of the second metal interconnect structures 340. The second semiconductor devices 320 may comprise any semiconductor device known in the art such as field effect transistors and passive devices. Second shallow trench isolation structures 312 may be provided within the second semiconductor substrate 309 such that neighboring pairs of second semiconductor devices 320 are electrically isolated from each other. All of the sidewalls of the second semiconductor die 300 may be physically exposed.

The second active bonding pads 388A may be bonded to the first active bonding pads 228A through metal-to-metal bonding such as copper to copper bonding. The second dummy bonding pads 388D may be bonded to the first dummy bonding pads 228D through metal-to-metal bonding such as copper to copper bonding. Additionally, a horizontal bottom surface of the second bonding-level dielectric layer 370 may be bonded to a topmost surface of the at least one bonding-level dielectric layer 220 by dielectric-to-dielectric bonding such as silicon oxide-to-silicon oxide bonding

In one embodiment, the second semiconductor die 300 comprises an edge seal ring structure 344 that extends continuously along all sidewalls of the second semiconductor die 300. In one embodiment, at least one first dummy bonding pad 228D within the first subset of the first dummy bonding pads 228D overlaps with the edge seal ring structure 344 in the plan view. Additionally or alternatively, at least one first dummy bonding pad 228D within the first subset of the first dummy bonding pads 228D is at least partly within an area enclosed by the edge seal ring structure 344 in the plan view. Additionally or alternatively, at least one first dummy bonding pad 228D within the first subset of the first dummy bonding pads 228D is located at least partly within a frame-shaped area located between an outer periphery of the edge seal ring structure 344 and sidewalls of the second semiconductor die 300 in the plan view.

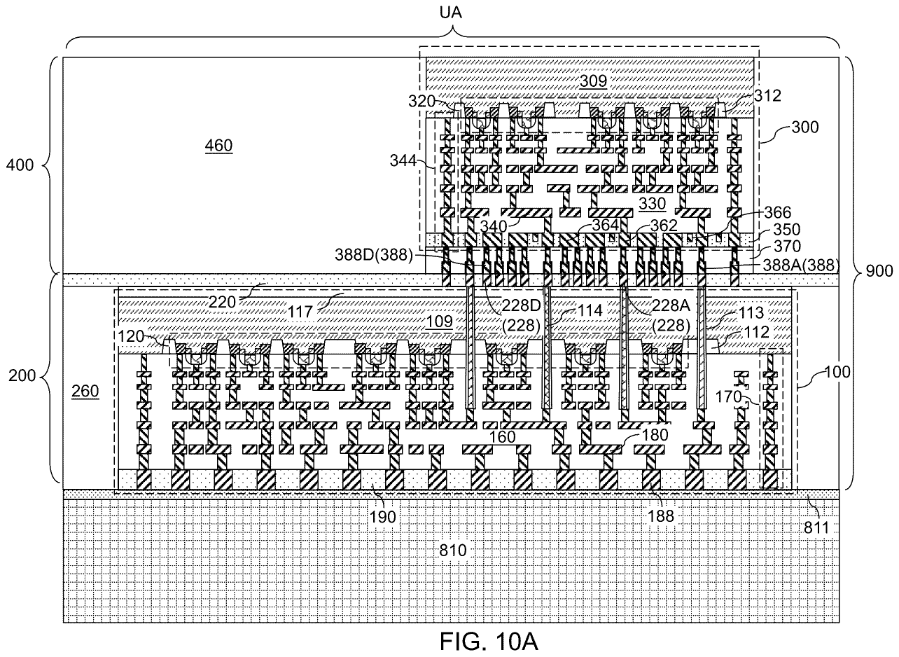

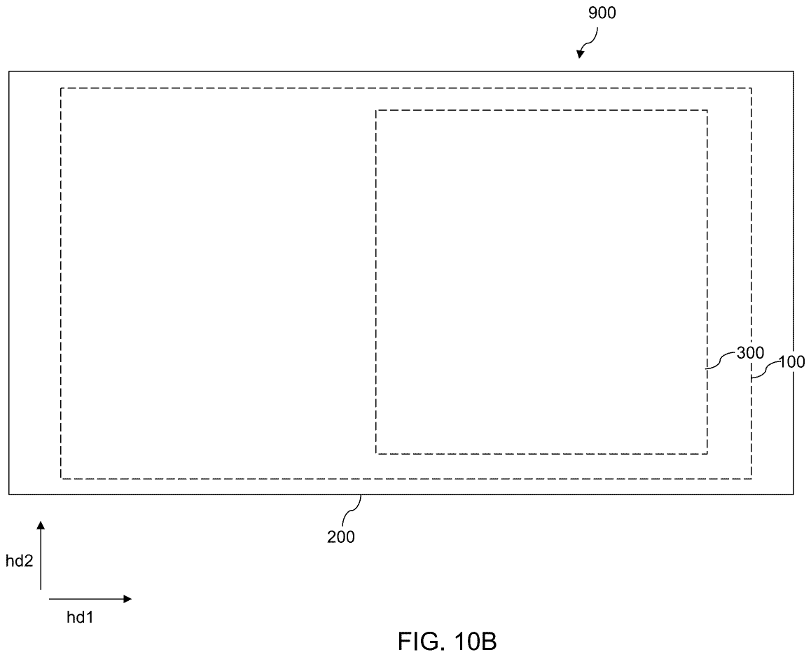

Referring to FIGS. 10A and 10B, a second molding compound matrix 460 may be formed around the second semiconductor dies 300. Specifically, a second molding compound may be applied to the gaps between neighboring pairs of the second semiconductor dies 300. The second molding compound may comprise any material that may be used as the first molding compound. Generally, the second molding compound and the first molding compound may have the same material composition or may have different material compositions. The second molding compound may be cured at a curing temperature to form a second molding compound matrix 460 that laterally surrounds the two-dimensional array of the second semiconductor dies 300.

The second molding compound matrix 460 comprise a plurality of second molding compound die frames that are interconnected to one another. Each second molding compound die frame is a portion of the second molding compound matrix 460 that is located within an area of a repetition unit within a two-dimensional periodic array of structures overlying the carrier substrate 810. Thus, each second molding compound die frame laterally surrounds and embeds a respective second semiconductor die 300.

Portions of the second molding compound matrix 460 that overlie the horizontal plane including the top surfaces of the second semiconductor dies 300 may be removed by a planarization process. For example, the portions of the second molding compound matrix 460 that overlies the horizontal plane may be removed using a chemical mechanical planarization (CMP). The combination of the remaining portion of the second molding compound matrix 460 and the array of second semiconductor dies 300 comprises second molded die units 400. Each second molded die unit 400 comprises a second semiconductor die 300 and a portion of the second molding compound matrix 460 located within a unit area. Each portion of the second molding compound matrix 460 located within a unit area constitutes a second molding compound die frame. Generally, a second molding compound matrix 460 may be formed around a second semiconductor die 300 such that a top surface of the second molding compound matrix 460 is coplanar with a top surface of the second semiconductor die 300. Each vertical stack of a first molded die unit 200 and a second molded die unit 400 constitutes a composite die 900. A two-dimensional array of composite dies 900 may be formed over the carrier substrate 810.

Subsequently, the carrier substrate 810 may be detached from a reconstituted wafer including a two-dimensional array of composite dies 900 by decomposing the adhesive layer 811. A thermal anneal process or an ultraviolet irradiation process may be used to decompose the adhesive layer 811. A suitable clean process may be performed to clean the physically exposed surfaces of the first bonding-level dielectric layer 190 and the package bonding structures 188.

The reconstituted wafer may be diced along dicing channels to singulate the composite dies 900. Each composite die 900 comprises an assembly of a first semiconductor die 100; a first molding compound matrix 260 (which is a first molding compound die frame); a combination of at least one bonding-level dielectric layer 220, first active bonding pads 228A, and first dummy bonding pads 228D; a second semiconductor die 300 including second bonding pads 388 that are bonded to the first active bonding pads 228A via metal-to-metal bonding; and a second molding compound matrix 460 (which is a second molding compound die frame). In one embodiment, each composite die 900 may have a pair of first sidewalls that are parallel to a first horizontal direction hd1 and a pair of second sidewalls that are parallel to a second horizontal direction hd2 that is perpendicular to the first horizontal direction hd1.

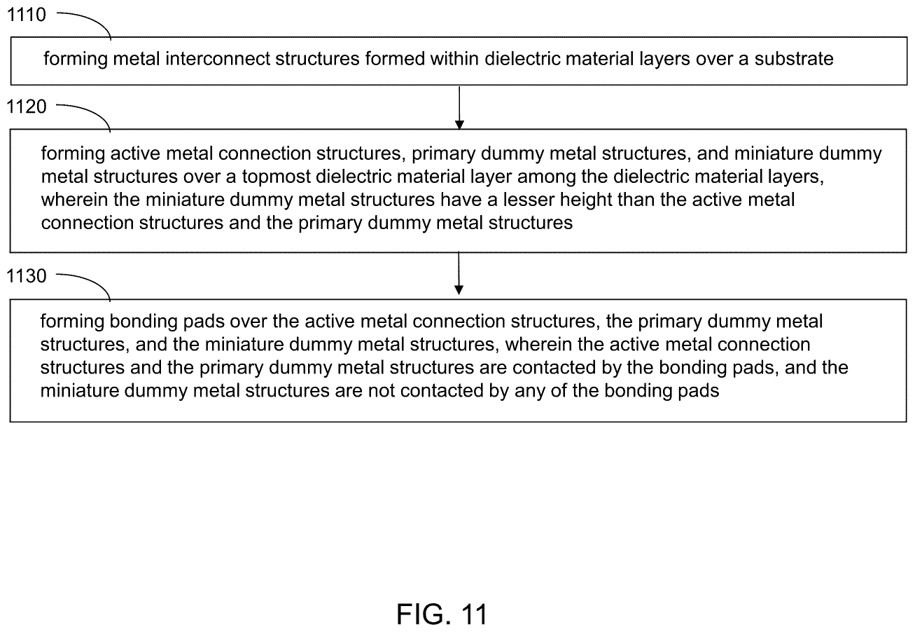

Referring to FIG. 11, a first flowchart illustrates steps for forming a device structure.

Referring to step 1110 and FIGS. 1 and 2A, metal interconnect structures 340 embedded in dielectric material layers 330 may be formed over a substrate.

Referring to step 1120 and FIG. 2B-2H and 3A-3G, active metal connection structures 362, primary dummy metal structures 364, and miniature dummy metal structures 366 may be formed over a topmost dielectric material layer 33T selected from the dielectric material layers 330. The miniature dummy metal structures 366 have a lesser height than the active metal connection structures 362 and the primary dummy metal structures 364.

Referring to step 1130 and FIG. 4A-10B, bonding pads 388 may be formed over the active metal connection structures 362, the primary dummy metal structures 364, and the miniature dummy metal structures 366. The active metal connection structures 362 and the primary dummy metal structures 364 are contacted by the bonding pads 388, and the miniature dummy metal structures 366 are not contacted by any of the bonding pads 388.

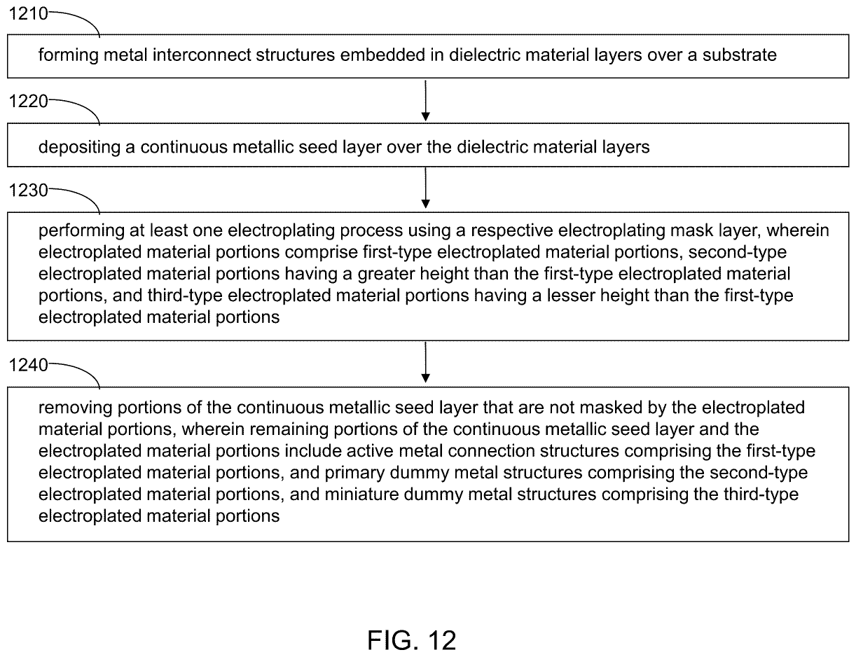

Referring to FIG. 12, a second flowchart illustrates steps for forming a device structure.

Referring to step 1210 and FIGS. 1 and 2A, metal interconnect structures 340 embedded in dielectric material layers 330 may be formed over a substrate.

Referring to step 1220 and FIGS. 2B and 2C, a continuous metallic seed layer 368C may be formed over the dielectric material layers 330.

Referring to step 1230 and FIG. 2D-2F and 3A-3F, at least one electroplating process may be performed using a respective electroplating mask layer {357 or (353, 355)} to form electroplated material portions (362M, 364M, 366M). The electroplated material portions (362M, 364M, 366M) comprise first-type electroplated material portions 362M, second-type electroplated material portions 364M having a greater height than the first-type electroplated material portions 362M, and third-type electroplated material portions 366M having a lesser height than the first-type electroplated material portions 362M.

Referring to step 1240 and FIGS. 2G, 2H, 3G, and 4A-10B, portions of the continuous metallic seed layer 368C that are not masked by the electroplated material portions (362M, 364M, 366M) may be removed. Remaining portions of the continuous metallic seed layer 368C and the electroplated material portions (362M, 364M, 366M) include active metal connection structures 362 comprising the first-type electroplated material portions 362M, primary dummy metal structures 364 comprising the second-type electroplated material portions 364M, and miniature dummy metal structures 366 comprising the third-type electroplated material portions 366M.

Referring to all drawings and according to various embodiments of the present disclosure, a device structure is provided, which comprises: metal interconnect structures 340 embedded in dielectric material layers 330; active metal connection structures 362, primary dummy metal structures 364, and miniature dummy metal structures 366 located over a topmost dielectric material layer 33T selected from the dielectric material layers 330, wherein the miniature dummy metal structures 366 have a lesser height than the active metal connection structures 362 and the primary dummy metal structures 364; and bonding pads 388 located over the active metal connection structures 362, the primary dummy metal structures 364, and the miniature dummy metal structures 366, wherein the active metal connection structures 362 and the primary dummy metal structures 364 are contacted by the bonding pads 388, and the miniature dummy metal structures 366 are not contacted by any of the bonding pads 388.

In one embodiment, each of the active metal connection structures 362, the primary dummy metal structures 364, and the miniature dummy metal structures 366 comprises a respective bottom surface located within a horizontal plane including a top surface of the topmost dielectric material layer 33T. In one embodiment, each of the active metal connection structures 362 comprises a respective via portion that vertically extends through the topmost dielectric material layer 33T and contacts a respective one of the metal interconnect structures 340; and each of the primary dummy metal structures 364, and the miniature dummy metal structures 366 is located entirely above a horizontal plane including a top surface of the topmost dielectric material layer 33T. In one embodiment, the device structure comprises a connection-level dielectric layer 350 laterally surrounding the active metal connection structures 362, the primary dummy metal structures 364, and the miniature dummy metal structures 366, wherein top surfaces of the active metal connection structures 362 and the primary dummy metal structures 364 are located within a horizontal plane including a top surface of the connection-level dielectric layer, and top surfaces of the miniature dummy metal structures 366 are located below the horizontal plane. In one embodiment, each of the active metal connection structures 362 contacts a respective one of the metal interconnect structures 340; and the primary dummy metal structures 364 and the miniature dummy metal structures 366 do not contact any of the metal interconnect structures 340.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming metal interconnect structures embedded in dielectric material layers over a substrate;
forming active metal connection structures, primary dummy metal structures, and miniature dummy metal structures over a topmost dielectric material layer selected from the dielectric material layers, wherein the miniature dummy metal structures have a lesser height than the active metal connection structures and the primary dummy metal structures; and
forming bonding pads over the active metal connection structures, the primary dummy metal structures, and the miniature dummy metal structures, wherein the active metal connection structures and the primary dummy metal structures are contacted by the bonding pads, and the miniature dummy metal structures are not contacted by any of the bonding pads.

2. The method of claim 1, wherein each of the miniature dummy metal structures is electrically isolated from the metal interconnect structures, the bonding pads, the active metal connection structures, and the primary dummy metal structures.

3. The method of claim 1, further comprising:
depositing a continuous metallic seed layer over the dielectric material layers;
forming a patterned electroplating mask layer over the continuous metallic seed layer;
electroplating a metallic material on physically exposed surfaces of the continuous metallic seed layer; and
removing the patterned electroplating mask layer and unmasked portions of the continuous metallic seed layer, wherein remaining portions of the continuous metallic seed layer and the electroplated metallic material comprise the active metal connection structures, the primary dummy metal structures, and the miniature dummy metal structures.

4. The method of claim 3, further comprising forming via cavities through a topmost dielectric material layer selected from the dielectric material layers, wherein top surfaces of a subset of the metal interconnect structures are exposed underneath the via cavities, and wherein the continuous metallic seed layer is deposited directly on the subset of the metal interconnect structures.

5. The method of claim 4, wherein:
each of the active metal connection structures contacts a respective metal interconnect structure selected from the subset of the metal interconnect structures; and
the primary dummy metal structures do not contact any of the metal interconnect structures.

6. The method of claim 4, wherein each of the primary dummy metal structures and the miniature dummy metal structures is formed entirely in a region in which via cavities are absent.

7. The method of claim 4, wherein each of the primary dummy metal structures and the miniature dummy metal structures is formed entirely above a horizontal plane including a top surface of the topmost dielectric material layer.

8. The method of claim 1, further comprising:
forming a connection-level dielectric layer over the active metal connection structures, the primary dummy metal structures, and the miniature dummy metal structures; and
planarizing portions of the connection-level dielectric layer, the active metal connection structures, and the primary dummy metal structures that overlie a horizontal plane by performing a chemical mechanical polishing process, wherein the horizontal plane is located above top surfaces of the miniature dummy metal structures.

9. The method of claim 8, further comprising:
forming a bonding-level dielectric layer over the connection-level dielectric layer, the active metal connection structures, the primary dummy metal structures, and the miniature dummy metal structures;
forming pad cavities through the bonding-level dielectric layer, wherein top surface segments of the active metal connection structures and the primary dummy metal structures are exposed under the pad cavities; and
forming the bonding pads in the pad cavities.

10. A method of forming a device structure, comprising:
forming metal interconnect structures embedded in dielectric material layers over a substrate;
depositing a continuous metallic seed layer over the dielectric material layers;
performing at least one electroplating process using a respective electroplating mask layer to form electroplated material portions, wherein the electroplated material portions comprise first-type electroplated material portions, second-type electroplated material portions having a greater height than the first-type electroplated material portions, and third-type electroplated material portions having a lesser height than the first-type electroplated material portions; and
removing portions of the continuous metallic seed layer that are not masked by the electroplated material portions, wherein remaining portions of the continuous metallic seed layer and the electroplated material portions include active metal connection structures comprising the first-type electroplated material portions, primary dummy metal structures comprising the second-type electroplated material portions, and miniature dummy metal structures comprising the third-type electroplated material portions.

11. The method of claim 10, wherein the miniature dummy metal structures have a lesser height than the active metal connection structures and the primary dummy metal structures.

12. The method of claim 10, further comprising forming bonding pads over the active metal connection structures, the primary dummy metal structures, and the miniature dummy metal structures, wherein the active metal connection structures and the primary dummy metal structures are contacted by the bonding pads, and the miniature dummy metal structures are not contacted by any of the bonding pads.

13. The method of claim 10, wherein:
the first-type electroplated material portions, the second-type electroplated material portions, and the third-type electroplated material portions are formed simultaneously in a single electroplating process; and
the first-type electroplated material portions have greater lateral dimensions than the third-type electroplated material portions.

14. The method of claim 10, wherein:
the first-type electroplated material portions and the second-type electroplated material portions are formed by performing an electroplating process using a patterned electroplating mask layer; and
the third-type electroplated material portions are formed by performing an additional electroplating process using an additional patterned electroplating mask layer.

15. The method of claim 10, wherein:
the first-type electroplated material portions comprise active electroplated material portions that are electrically connected to a respective one of the metal interconnect structures;
the second-type electroplated material portions comprise first dummy electroplated material portions that are electrically isolated from the metal interconnect structures and have top surfaces that are formed above a horizontal plane including top surfaces of the active electroplated material portions; and
the third-type electroplated material portions comprise second dummy electroplated material portions that are electrically isolated from the metal interconnect structures and have top surfaces that are formed below the horizontal plane.

16. A device structure comprising:
metal interconnect structures embedded in dielectric material layers;
active metal connection structures, primary dummy metal structures, and miniature dummy metal structures located over a topmost dielectric material layer selected from the dielectric material layers, wherein the miniature dummy metal structures have a lesser height than the active metal connection structures and the primary dummy metal structures; and
bonding pads located over the active metal connection structures, the primary dummy metal structures, and the miniature dummy metal structures, wherein the active metal connection structures and the primary dummy metal structures are contacted by the bonding pads, and the miniature dummy metal structures are not contacted by any of the bonding pads.

17. The device structure of claim 16, wherein each of the active metal connection structures, the primary dummy metal structures, and the miniature dummy metal structures comprises a respective bottom surface located within a horizontal plane including a top surface of the topmost dielectric material layer.

18. The device structure of claim 16, wherein:
each of the active metal connection structures comprises a respective via portion that vertically extends through the topmost dielectric material layer and contacts a respective one of the metal interconnect structures; and
each of the primary dummy metal structures, and the miniature dummy metal structures is located entirely above a horizontal plane including a top surface of the topmost dielectric material layer.

19. The device structure of claim 16, further comprising a connection-level dielectric layer laterally surrounding the active metal connection structures, the primary dummy metal structures, and the miniature dummy metal structures, wherein top surfaces of the active metal connection structures and the primary dummy metal structures are located within a horizontal plane including a top surface of the connection-level dielectric layer, and top surfaces of the miniature dummy metal structures are located below the horizontal plane.

20. The device structure of claim 16, wherein:
each of the active metal connection structures contacts a respective one of the metal interconnect structures; and
the primary dummy metal structures and the miniature dummy metal structures do not contact any of the metal interconnect structures.
